(19) United States
(12) Patent Application Publication
(10) Pub. No.: US 2024/0282547 A1
(43) Pub. Date: Aug. 22, 2024

(54) MULTI-ELECTRON BEAM IMAGE ACQUISITION APPARATUS AND MULTI-ELECTRON BEAM IMAGE ACQUISITION METHOD

(71) Applicant: NuFlare Technology, Inc., Yokohama-shi (JP)

(72) Inventors: Koichi ISHII, Kawasaki-shi (JP); Atsushi ANDO, Edogawa-ku (JP)

(73) Assignee: NuFlare Technology, Inc., Yokohama-shi (JP)

(21) Appl. No.: 18/647,061

(22) Filed: Apr. 26, 2024

Related U.S. Application Data
(63) Continuation of application No. PCT/JP2022/030222, filed on Aug. 8, 2022.

(30) Foreign Application Priority Data
Oct. 26, 2021 (JP) 2021-174613

(51) Int. Cl. H01J 37/153; H01J 37/147; H01J 37/244; H01J 37/28; H01J 37/317

(52) U.S. Cl. CPC H01J 37/153; H01J 37/1474; H01J 37/244; H01J 37/3177; H01J 37/28; H01J 2237/1501; H01J 2237/2448; H01J 2237/2817; H01J 2237/31776

(57) ABSTRACT

A multi-electron beam image acquisition apparatus includes a multiple primary electron beams forming device to form multiple primary electron beams, a first-deflector to scan the multiple-primary electron beams over a target object by deflecting the multiple-primary electron beams, a corrector to correct a beam-array-distribution-shape of multiple-secondary electron beams emitted from the target object irradiated with the multiple-primary electron beams, a second-deflector to deflect the multiple-secondary electron beams whose beam-array-distribution-shape has been corrected, a detector to detect the deflected multiple-secondary electron beams, and a deflection control circuit to control applying, to the second-deflector, a superimposed potential obtained by superimposing a deflection potential which cancels out a position movement of the multiple-secondary electron beams moved along with scanning the multiple-primary electron beams on a correction potential which corrects a distortion being generated due to correcting the beam-array-distribution-shape of the multiple-secondary electron beams and being dependent on a deflection amount for scanning.

### CROSS-REFERENCE TO RELATED APPLICATION

This application is a continuation application based upon and claims the benefit of priority from prior Japanese Patent Application No. 2021-174613 (application number) filed on Oct. 26, 2021 in Japan, and International Application PCT/JP2022/030222, the International Filing Date of which is Aug. 8, 2022. The contents described in JP2021-174613 and PCT/JP2022/030222 are incorporated herein by reference.

### BACKGROUND OF THE INVENTION

### Field of the Invention

Embodiments of the present invention relate to a multi-electron beam image acquisition method and a multi-electron beam image acquisition apparatus, and for example, relate to a method for acquiring an image by applying multiple primary electron beams to a substrate and detecting multiple secondary electron beams emitted from the substrate due to the irradiation with the multiple primary electron beams.

### Description of Related Art

With recent progress in high integration and large capacity of the Large Scale Integrated circuits (LSI), the line width (critical dimension) required for circuits of semiconductor elements is becoming increasingly narrower. Since LSI manufacturing requires an enormous production cost, it is essential to improve the yield. However, as typified by 1 gigabit DRAMs (Dynamic Random Access Memories), the size of patterns that make up LSIs becomes the order of nanometers from submicrons. Also, in recent years, with miniaturization of dimensions of LSI patterns formed on a semiconductor wafer, dimensions to be detected as a pattern defect have become extremely small. Therefore, the pattern inspection apparatus which inspects defects of ultrafine patterns exposed (transferred) to the semiconductor wafer needs to be highly accurate. Further, one of major factors that decrease the yield is due to pattern defects on the mask used for exposing (transferring) ultrafine patterns onto the semiconductor wafer by the photolithography technology. Accordingly, the pattern inspection apparatus for inspecting defects on an exposure transfer mask used in manufacturing LSI needs to be highly accurate.

The inspection apparatus acquires a pattern image by, for example, irradiating an inspection target substrate with multiple electron beams and detecting a secondary electron corresponding to each beam emitted from the inspection target substrate. As an inspection method, there is known a method of comparing a measured image acquired by imaging a pattern formed on a substrate with design data or with another measured image acquired by imaging an identical pattern on the same substrate. For example, as pattern inspection methods, there are a “die-to-die inspection” method and a “die-to-database inspection” method. Specifically, the “die-to-die inspection” method compares data of measured images acquired by imaging identical patterns at different positions on the same substrate. The “die-to-database inspection” method generates design image data (reference image) based on pattern design data, and compares it with a measured image being measured data acquired by imaging a pattern. Acquired images are transmitted as measured data to a comparison circuit. After performing alignment between the images, the comparison circuit compares the measured data with reference data according to an appropriate algorithm, and determines that there is a pattern defect if the compared data do not match each other.

When acquiring an image by using multiple beams, multiple primary electron beams are scanned over a predetermined range of the substrate. Accordingly, the emission position of each secondary electron beam changes every second. In order to apply each secondary electron beam whose emission position has changed to a corresponding detection region of a multi-detector, it is necessary to perform a swing-back deflection of the multiple secondary electron beams so as to cancel out the position movement of the multiple secondary electron beams caused by the change of the emission position.

Then, as for the multiple secondary electron beams, their beam array distribution shape is corrected, using an astigmatism corrector, etc., between the position where deflection of the multiple primary electron beams is performed along with scanning and the position where a swing-back deflection of the multiple secondary electron beams is performed. However, in the case of correcting the beam array distribution shape of the multiple secondary electron beams while performing scanning with the multiple primary electron beams, even if the multiple secondary electron beams having been corrected are swing-back deflected, there is a problem that an error occurs at a position having been swung back.

Although not relating to multiple beams, correction of deflection aberration is disclosed, which is executed by adding a correction voltage for correcting field curvature aberration to a correction voltage for correcting astigmatism, and applying an added correction voltage to each electrode of a deflector (e.g., refer to Japanese Patent Application Laid-open (JP-A) No. 2007-188950).

### BRIEF SUMMARY OF THE INVENTION

According to one aspect of the present invention, a multi-electron beam image acquisition apparatus includes
a stage configured to mount thereon a target object,
a multiple primary electron beams forming device configured to form multiple primary electron beams,
a first deflector configured to scan the multiple primary electron beams over the target object by deflecting the multiple primary electron beams,
a corrector configured to correct a beam array distribution shape of multiple secondary electron beams emitted because the target object is irradiated with the multiple primary electron beams,
a second deflector configured to deflect the multiple secondary electron beams whose the beam array distribution shape has been corrected,
a detector configured to detect the multiple secondary electron beams having been deflected, and
a deflection control circuit configured to perform controlling to apply, to the second deflector, a superimposed potential obtained by superimposing a deflection potential which cancels out a position movement of the multiple secondary electron beams having moved along with scanning the multiple primary electron beams on a correction potential which corrects a distortion being generated due to correcting the beam array distribution shape of the multiple secondary electron beams and being dependent on a deflection amount for the scanning.

According to another aspect of the present invention, a multi-electron beam image acquisition apparatus includes
a stage configured to mount thereon a target object,
a multiple primary electron beams forming device configured to form multiple primary electron beams,
a first deflector configured to scan the multiple primary electron beams over the target object by deflecting the multiple primary electron beams,
a second deflector configured to cancel out, by deflecting multiple secondary electron beams emitted because the target object is irradiated with the multiple primary electron beams, a position movement of the multiple secondary electron beams having moved along with scanning the multiple primary electron beams,
a corrector configured to correct a beam array distribution shape of the multiple secondary electron beams whose the position movement has been cancelled out by the deflecting the multiple secondary electron beams, and
a detector configured to detect the multiple secondary electron beams whose the beam array distribution shape has been corrected.

According to yet another aspect of the present invention, a multi-electron beam image acquisition method includes
forming multiple primary electron beams,
scanning, by a first deflector, the multiple primary electron beams over a target object mounted on a stage by deflecting the multiple primary electron beams,
correcting a beam array distribution shape of multiple secondary electron beams emitted because the target object is irradiated with the multiple primary electron beams,
deflecting the multiple secondary electron beams, whose the beam array distribution shape has been corrected, by a second deflector to which has been applied a superimposed potential obtained by superimposing a deflection potential for cancelling out a position movement of the multiple secondary electron beams having moved along with the scanning the multiple primary electron beams on a correction potential for correcting a distortion being generated due to the correcting the beam array distribution shape of the multiple secondary electron beams and being dependent on a deflection amount for the scanning, and
detecting the multiple secondary electron beams having been deflected, and outputting detection image data.

According to yet another aspect of the present invention, a multi-electron beam image acquisition method includes
forming multiple primary electron beams,
scanning, by a first deflector, the multiple primary electron beams over a target object mounted on a stage by deflecting the multiple primary electron beams,
cancelling out a position movement of multiple secondary electron beams, which are emitted because the target object is irradiated with the multiple primary electron beams, having moved along with the scanning the multiple primary electron beams by deflecting the multiple secondary electron beams by a second deflector,
correcting a beam array distribution shape of the multiple secondary electron beams whose the position movement has been cancelled out by the deflecting the multiple secondary electron beams, and
detecting the multiple secondary electron beams whose the beam array distribution shape has been corrected, and outputting detection image data.

### BRIEF DESCRIPTION OF THE DRAWINGS

FIG. 1 is a diagram showing a configuration of an inspection apparatus according to a first embodiment;

FIG. 2 is a conceptual diagram showing a configuration of a shaping aperture array substrate according to the first embodiment;

FIG. 3 is an illustration showing an example of a plurality of chip regions formed on a semiconductor substrate, according to the first embodiment;

FIG. 4 is an illustration describing inspection processing according to the first embodiment;

FIG. 5A is an illustration showing an example of the structure of a multipole corrector and an example of an excited state according to the first embodiment;

FIG. 5B is an illustration showing an example of a structure of a multipole corrector and another example of an excited state according to the first embodiment;

FIG. 6A is an illustration showing an example of the structure of a multipole corrector and another example of an excited state according to the first embodiment;

FIG. 6B is an illustration showing an example of the structure of a multipole corrector and another example of an excited state according to the first embodiment;

FIG. 7 is an illustration showing an example of a beam array distribution shape according to the first embodiment;

FIG. 8 is a diagram showing an example of the internal configuration of a deflection adjustment circuit according to the first embodiment;

FIG. 9 is a flowchart showing main steps of an inspection method according to the first embodiment;

FIG. 10 is an illustration showing an example of a primary scanning region according to the first embodiment;

FIG. 11 is an illustration showing an example of an image of a beam detection position at each deflection position in the primary scanning region according to the first embodiment;

FIG. 12 is an illustration showing an example of an image of the beam detection position at each deflection position of the secondary scanning before performing a swing-back correction according to the first embodiment;

FIG. 13 is an illustration showing an example of a combined image acquired before a swing-back correction according to the first embodiment;

FIG. 14 is an illustration explaining an influence of correcting a beam array distribution shape according to the first embodiment;

FIG. 15 is an illustration explaining each electrode of a deflector and an electric potential applied to the each electrode in the secondary system according to the first embodiment;

FIG. 16 is a diagram showing an example of a conversion table according to the first embodiment;

FIG. 17 is an illustration showing an example of an image of a beam detection position at each deflection position of the secondary scanning after a swing-back correction according to the first embodiment;

FIG. 18 is an illustration showing an example of a combined image acquired after a swing-back correction according to the first embodiment;

FIG. 19 is a diagram showing an example of the internal configuration of a comparison circuit according to the first embodiment;

FIG. 20 is a diagram showing an example of the configuration of an inspection apparatus according to a second embodiment;

FIG. 21 is an illustration showing an example of an image of a beam detection position at each deflection position of the primary scanning before performing a swing-back correction according to the second embodiment;

FIG. 22 is an illustration showing an example of an image of a beam detection position at each deflection position of the secondary scanning before performing a swing-back correction according to the second embodiment;

FIG. 23 is an illustration showing an example of a combined image acquired before a swing-back correction according to the second embodiment;

FIG. 24 is an illustration showing an example of an image of a beam detection position at each deflection position of the secondary scanning after a swing-back correction according to the second embodiment;

FIG. 25 is an illustration showing an example of a combined image acquired after a swing-back correction according to the second embodiment; and

FIG. 26 is an illustration for explaining a scanning operation by a two-stage deflector in each Embodiment.

### DETAILED DESCRIPTION OF THE INVENTION

Embodiments of the present invention provide an apparatus and method that can, in the case of correcting a beam array distribution shape of multiple secondary electron beams, reduce an error occurred after a swing-back deflection of the multiple secondary electron beams executed for cancelling out a position movement of the multiple secondary electron beams having moved along with scanning the multiple primary electron beams.

The embodiments below describe, as an example of a multi-electron beam image acquisition apparatus, an inspection apparatus using multiple electron beams. However, it is not limited thereto. Any apparatus can be used that acquires an image by irradiating a substrate with multiple primary electron beams to utilize multiple secondary electron beams emitted from the substrate due to the irradiation.

### First Embodiment

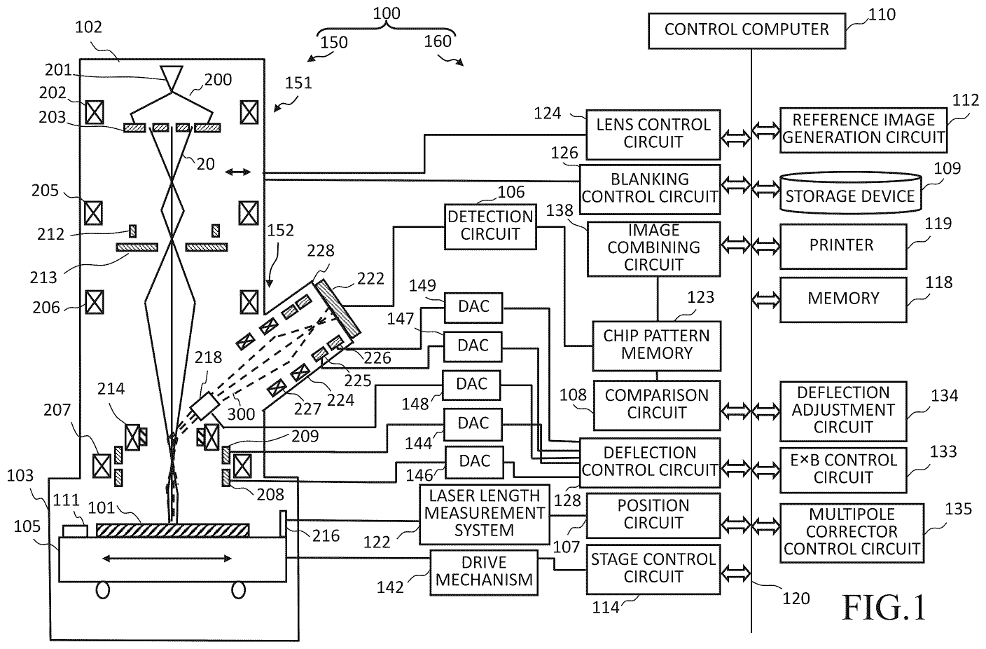

FIG. 1 is a diagram showing an example of the configuration of an inspection apparatus according to a first embodiment. In FIG. 1, an inspection apparatus 100 for inspecting a pattern formed on a substrate is an example of a multi-electron beam inspection apparatus. The inspection apparatus 100 includes an image acquisition mechanism 150 and a control system circuit 160. The image acquisition mechanism 150 includes an electron beam column 102 (electron optical column) and an inspection chamber 103. In the electron beam column 102, there are disposed an electron gun 201, an electromagnetic lens 202, a shaping aperture array substrate 203, an electromagnetic lens 205, a collective blanking deflector 212, a limiting aperture substrate 213, an electromagnetic lens 206, an electromagnetic lens 207 (objective lens), deflectors 208 and 209, an E×B separator 214 (beam separator), a deflector 218, a multipole corrector 227, an electromagnetic lens 224, deflectors 225 and 226, a detector aperture array substrate 228, and a multi-detector 222. A primary electron optical system 151 (illumination optical system) is composed of the electron gun 201, the electromagnetic lens 202, the shaping aperture array substrate 203, the electromagnetic lens 205, the collective blanking deflector 212, the limiting aperture substrate 213, the electromagnetic lens 206, the electromagnetic lens 207 (objective lens), and the deflectors 208 and 209. A secondary electron optical system 152 (detection optical system) is composed of the electromagnetic lens 207, the E×B separator 214, the deflector 218, the multipole corrector 227, the electromagnetic lens 224, and the deflectors 225 and 226. In FIG. 1, the two-stage deflector composed of the deflectors 208 and 209 may be a single stage deflector (e.g., deflector 209). The two-stage deflector composed of the deflectors 225 and 226 may be a single stage deflector (e.g., deflector 226).

In the inspection chamber 103, there is disposed a stage 105 movable at least in the x and y directions. On the stage 105, a substrate 101 (target object) to be inspected is placed. The substrate 101 may be an exposure mask substrate, or a semiconductor substrate such as a silicon wafer. In the case of the substrate 101 being a semiconductor substrate, a plurality of chip patterns (wafer die) are formed on the semiconductor substrate. In the case of the substrate 101 being an exposure mask substrate, a chip pattern is formed on the exposure mask substrate. The chip pattern is composed of a plurality of figure patterns. When the chip pattern formed on the exposure mask substrate is exposed and transferred onto the semiconductor substrate a plurality of times, a plurality of chip patterns (wafer die) are formed on the semiconductor substrate. The case of the substrate 101 being a semiconductor substrate is mainly described below. The substrate 101 is placed, with its pattern-forming surface facing upward, on the stage 105, for example. Further, on the stage 105, there is disposed a mirror 216 which reflects a laser beam for measuring a laser length emitted from a laser length measuring system 122 arranged outside the inspection chamber 103. Furthermore, on the XY stage 105, a mark 111 adjusted to be flush in height with the surface of the substrate 101 is arranged. For example, a cross pattern is formed as the mark 111.

The multi-detector 222 is connected, at the outside of the electron beam column 102, to a detection circuit 106. The detection circuit 106 is connected to a chip pattern memory 123.

The multi-detector 222 includes a plurality of detection elements arranged in an array. In the detector aperture array substrate 228, a plurality of openings are formed at the array pitch of the plurality of detection elements. Each of the plurality of openings is a circle, for example. The center position of each opening is formed to correspond to the center position of a corresponding detection element. The size of the opening is smaller than the region size of the electron detection surface of the detection element. The detector aperture array substrate 228 is not necessarily required.

In the control system circuit 160, a control computer 110 which controls the whole of the inspection apparatus 100 is connected, through a bus 120, to a position circuit 107, a comparison circuit 108, a reference image generation circuit 112, a stage control circuit 114, a lens control circuit 124, a blanking control circuit 126, a deflection control circuit 128, an E×B control circuit 133, a deflection adjustment circuit 134, a multipole corrector control circuit 135, an image combining circuit 138, a storage device 109 such as a magnetic disk drive, a memory 118, and a printer 119. The deflection control circuit 128 is connected to DAC (digital-to-analog conversion) amplifiers 144, 146, 147, 148 and 149. The DAC amplifier 146 is connected to the deflector 208, the DAC amplifier 144 is connected to the deflector 209, the DAC amplifier 148 is connected to the deflector 218, the DAC amplifier 147 is connected to the deflector 224, and the DAC amplifier 149 is connected to the deflector 226.

The chip pattern memory 123 is connected to the comparison circuit 108 and the image combining circuit 138. The stage 105 is driven by a drive mechanism 142 under the control of the stage control circuit 114. In the drive mechanism 142, for example, a drive system such as a three (x-, y-, and θ-) axis motor driving in the directions of x, y, and θ in the stage coordinate system is configured, and therefore, the stage 105 can be moved in the x, y, and θ directions. A step motor, for example, can be used as each of these x, y, and θ motors (not shown). The stage 105 is movable in the horizontal direction and the rotation direction by the x-, y-, and θ-axis motors. The movement position of the stage 105 is measured by the laser length measuring system 122, and supplied (transmitted) to the position circuit 107. Based on the principle of laser interferometry, the laser length measuring system 122 measures the position of the stage 105 by receiving a reflected light from the mirror 216. With respect to the stage coordinate system, the x, y, and θ directions of the primary coordinate system are set, for example, to a plane perpendicular to the optical axis of multiple primary electron beams 20.

The electromagnetic lenses 202, 205, 206, 207, and 224 are controlled by the lens control circuit 124. The E×B separator 214 is controlled by the E×B control circuit 133. The collective blanking deflector 212 is an electrostatic deflector composed of two or more electrodes (or poles), and each electrode is controlled by the blanking control circuit 126 through a DAC amplifier (not shown). The deflector 209 is an electrostatic deflector composed of four or more electrodes (or poles), and each electrode is controlled by the deflection control circuit 128 through the DAC amplifier 144. The deflector 208 is an electrostatic deflector composed of four or more electrodes (or poles), and each electrode is controlled by the deflection control circuit 128 through the DAC amplifier 146. The deflector 218 is an electrostatic deflector composed of four or more electrodes (or poles), and each electrode is controlled by the deflection control circuit 128 through the DAC amplifier 148. The deflector 225 is an electrostatic deflector composed of four or more electrodes (or poles), and each electrode is controlled by the deflection control circuit 128 through the DAC amplifier 147. The deflector 226 is an electrostatic deflector composed of four or more electrodes (or poles), and each electrode is controlled by the deflection control circuit 128 through the DAC amplifier 149.

The multipole corrector 227 is composed of four or more multipoles, and controlled by the multipole corrector control circuit 135. The multipole corrector 227 is arranged on the trajectory of multiple secondary electron beams 300 between the deflectors 209 and 226.

To the electron gun 201, there is connected a high voltage force supply circuit (not shown). The high voltage force supply circuit applies an acceleration voltage between a filament (cathode) (not shown) and an extraction electrode (anode) (not shown) in the electron gun 201. In addition to the applying the acceleration voltage, a voltage is applied to another extraction electrode (Wehnelt), and the cathode is heated to a predetermined temperature, and thereby, electrons from the cathode are accelerated to be emitted as an electron beam 200.

FIG. 1 shows configuration elements necessary for describing the first embodiment. Other configuration elements generally necessary for the inspection apparatus 100 may also be included therein.

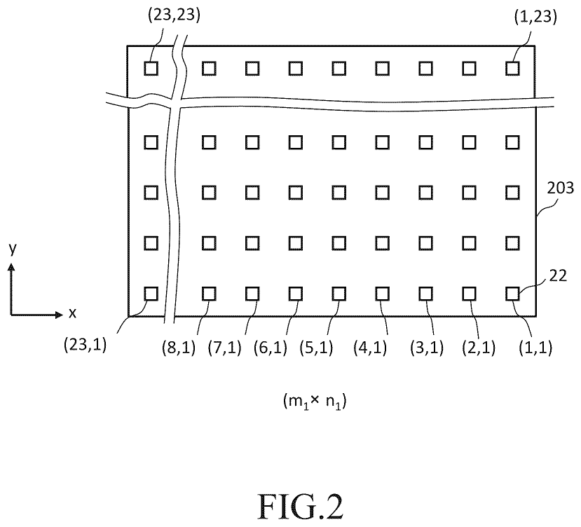

FIG. 2 is a conceptual diagram showing a configuration of a shaping aperture array substrate according to the first embodiment. As shown in FIG. 2, holes (openings) 22 of m₁ columns wide (in the x direction) and n₁ rows long (in the y direction), where each of m₁ and n₁ is an integer of 2 or more, are two-dimensionally formed in the x and y directions at a predetermined arrangement pitch in the shaping aperture array substrate 203. In the case of FIG. 2, 23×23 holes (openings) 22 are formed. Each of the holes 22 is a rectangle (including a square) having the same dimension, shape, and size. Alternatively, each of the holes 22 may be a circle with the same outer diameter. The multiple primary electron beams 20 are formed by letting portions of the electron beam 200 individually pass through a corresponding one of the plurality of holes 22. The shaping aperture array substrate 203 is an example of a multiple primary electron beams forming device. Next, operations of the image acquisition mechanism 150 in the case of acquiring a secondary electron image will be described below. The primary electron optical system 151 irradiates the substrate 101 with the multiple primary electron beams 20. Specifically, it operates as follows:

The electron beam 200 emitted from the electron gun 201 (emission source) is refracted by the electromagnetic lens 202, and illuminates the whole of the shaping aperture array substrate 203. As shown in FIG. 2, a plurality of holes 22 (openings) are formed in the shaping aperture array substrate 203. The region including all the plurality of holes 22 is irradiated with the electron beam 200. The multiple primary electron beams 20 are formed by letting portions of the electron beam 200 applied to the positions of the plurality of holes 22 individually pass through a corresponding one of the plurality of holes 22 in the shaping aperture array substrate 203.

The formed multiple primary electron beams 20 are individually refracted by the electromagnetic lenses 205 and 206, and, while repeating forming an intermediate image and a crossover, travel to the electromagnetic lens 207 (objective lens) passing through the E×B separator 214 arranged in the intermediate image plane of each beam of the multiple primary electron beams 20.

When the multiple primary electron beams 20 are incident on the electromagnetic lens 207 (objective lens), the electromagnetic lens 207 focuses the multiple primary electron beams 20 onto the substrate 101. The multiple primary electron beams 20 having been focused on the substrate 101 (target object) by the electromagnetic lens 207 are collectively deflected by the deflectors 208 and 209 to irradiate respective beam irradiation positions on the substrate 101. In the case where all of the multiple primary electron beams 20 are collectively deflected by the collective blanking deflector 212, they deviate from the hole in the center of the limiting aperture substrate 213 and all of them are blocked by the limiting aperture substrate 213. By contrast, the multiple primary electron beams 20 which were not deflected by the collective blanking deflector 212 pass through the hole in the center of the limiting aperture substrate 213 as shown in FIG. 1. Blanking control is provided by On/Off of the collective blanking deflector 212, and thus On/Off of the multiple beams is collectively controlled. In this way, the limiting aperture substrate 213 blocks the multiple primary electron beams 20 which were deflected to be in an “Off state” by the collective blanking deflector 212. Then, the multiple primary electron beams 20 for image acquisition are formed by the beams having been made during a period from becoming “beam On” to becoming “beam Off” and having passed through the limiting aperture substrate 213.

When desired positions on the substrate 101 are irradiated with the multiple primary electron beams 20, a flux of secondary electrons (multiple secondary electron beams 300), including reflected electrons, each corresponding to each beam of the multiple primary electron beams 20 is emitted from the substrate 101 due to the irradiation with the multiple primary electron beams 20.

The multiple secondary electron beams 300 emitted from the substrate 101 pass through the electromagnetic lens 207 and travel to the E×B separator 214. The E×B separator 214 includes a plurality of, at least two, magnetic poles each having a coil, and a plurality of, at least two, electrodes (poles). For example, the E×B separator 214 includes four magnetic poles (electromagnetic deflection coils) whose phases are mutually shifted by 90°, and four electrodes (electrostatic deflection electrodes) whose phases are also mutually shifted by 90°. For example, by setting two opposing magnetic poles to be an N pole and an S pole, a directive magnetic field is generated by these plurality of magnetic poles. Also, for example, by applying electrical potentials V whose signs are opposite to each other to the two opposing electrodes, a directive electric field is generated by these plurality of electrodes. Specifically, the E×B separator 214 generates an electric field and a magnetic field to be orthogonal to each other in a plane perpendicular to the traveling direction of the center beam (i.e., trajectory central axis) of the multiple primary electron beams 20. The electric field exerts a force in a fixed direction regardless of the traveling direction of electrons. In contrast, the magnetic field exerts a force according to Fleming's left-hand rule. Therefore, the direction of the force acting on (applied to) electrons can be changed depending on the entering (or “traveling”) direction of electrons. With respect to the multiple primary electron beams 20 entering the E×B separator 214 from above, since the forces due to the electric field and the magnetic field cancel each other out, the beams 20 travel straight downward. In contrast, with respect to the multiple secondary electron beams 300 entering the E×B separator 214 from below, since both the forces due to the electric field and the magnetic field are exerted in the same direction, the beams 300 are bent obliquely upward, and separated from the trajectory of the multiple primary electron beams 20.

The multiple secondary electron beams 300 having been bent obliquely upward are further bent by the deflector 218, and travel to the multipole corrector 227. In the multipole corrector 227, the beam array shape of the multiple secondary electron beams 300 is corrected so that it may be close to a quadrangle. The multiple secondary electron beams 300 having passed through the multipole corrector 227 are projected onto the multi-detector 222 while being refracted by the electromagnetic lens 224. The multi-detector 222 detects the projected multiple secondary electron beams 300 having passed through the openings of the detector aperture array substrate 228. At the detection surface of the multi-detector 222, since each beam of the multiple primary electron beams 20 collides with a detection element corresponding to each secondary electron beam of the multiple secondary electron beams 300, electron amplification occurs, and then, secondary electron image data is generated for each pixel. An intensity signal detected by the multi-detector 222 is output to the detection circuit 106. A sub-irradiation region on the substrate 101, which is surrounded with the x-direction beam pitch and the y-direction beam pitch and in which the beam concerned itself is located, is irradiated and scanned by each primary electron beam.

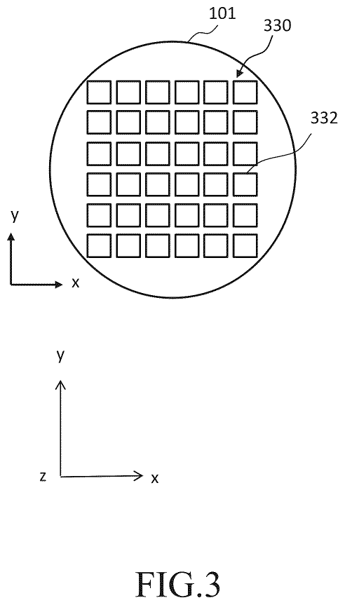

FIG. 3 is an illustration showing an example of a plurality of chip regions formed on a semiconductor substrate, according to the first embodiment. In FIG. 3, in the case of the substrate 101 being a semiconductor substrate (wafer), a plurality of chips (wafer dies) 332 are formed in a two-dimensional array in an inspection region 330 of the semiconductor substrate (wafer). A mask pattern for one chip formed on an exposure mask substrate is reduced to, for example, ¼, and exposed/transferred onto each chip 332 by an exposure device such as a stepper (not shown). The mask pattern for one chip is generally composed of a plurality of figure patterns.

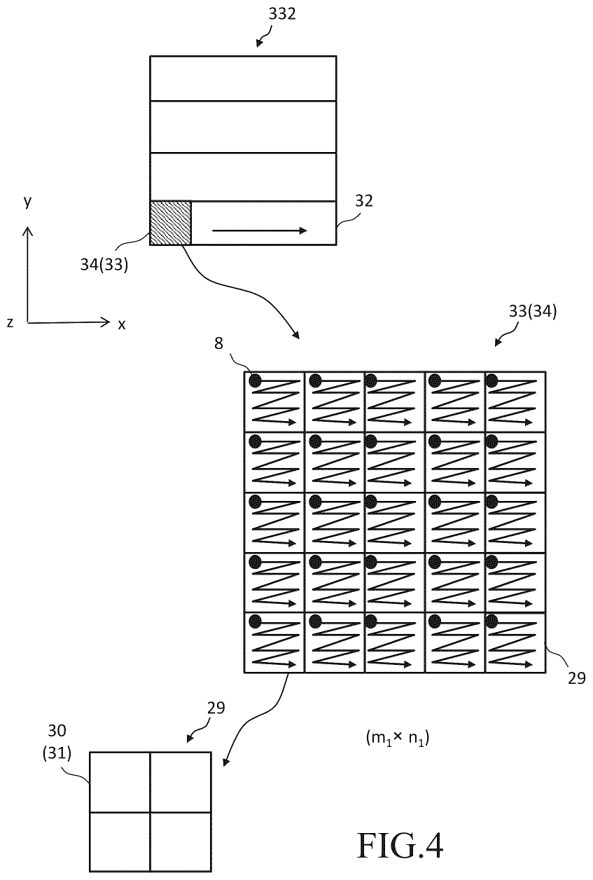

FIG. 4 is an illustration describing inspection processing according to the first embodiment. As shown in FIG. 4, the region of each chip 332 is divided, for example, in the y direction into a plurality of stripe regions 32 by a predetermined width. The scanning operation by the image acquisition mechanism 150 is carried out for each stripe region 32, for example. The operation of scanning the stripe region 32 advances relatively in the x direction while the stage 105 is moved in the −x direction, for example. Each stripe region 32 is divided in the longitudinal direction into a plurality of rectangular (including square) regions 33. Beam application to a target rectangular region 33 is achieved by collectively deflecting all the multiple primary electron beams 20 by the deflector 208.

The case of FIG. 4 shows the multiple primary electron beams 20 of 5 rows×5 columns, for example. The size of an irradiation region 34 which can be irradiated by one irradiation with the multiple primary electron beams 20 is defined by (x direction size obtained by multiplying an x-direction beam pitch by the number of x-direction beams of the multiple primary electron beams 20 on the substrate 101)×(y direction size obtained by multiplying a y-direction beam pitch by the number of y-direction beams of the multiple primary electron beams 20 on the substrate 101). The irradiation region 34 serves as a field of view of the multiple primary electron beams 20. A sub-irradiation region 29, which is surrounded by the x-direction beam pitch and the y-direction beam pitch and in which the beam concerned itself is located, is irradiated and scanned (scanning operation) with each primary electron beam 8 of the multiple primary electron beams 20. Each primary electron beam 8 is associated with any one of the sub-irradiation regions 29 which are different from each other. At the time of each shot, each primary electron beam 8 is applied to the same position in the associated sub-irradiation region 29. The primary electron beam 8 is moved in the sub-irradiation region 29 by collective deflection of all the multiple primary electron beams 20 by the deflector 209. By repeating this operation, the inside of one sub-irradiation region 29 is irradiated, in order, with one primary electron beam 8.

Preferably, the width of each stripe region 32 is set to be the same as the y-direction size of the irradiation region 34, or to be the size reduced by the width of the scanning margin. In the case of FIG. 4, the irradiation region 34 and the rectangular region 33 are of the same size. However, it is not limited thereto. The irradiation region 34 may be smaller than the rectangular region 33, or larger than it. Using each primary electron beam 8 of the multiple primary electron beams 20, the sub-irradiation region 29 in which the primary electron beam 8 concerned itself is located is irradiated with the primary electron beam 8 concerned, and scanned by collective deflection of all the multiple primary electron beams 20 by the deflector 209. Then, when scanning of one sub-irradiation region 29 is completed, the irradiation position is moved to an adjacent rectangular region 33 in the same stripe region 32 by collectively deflecting all the multiple primary electron beams 20 by the deflector 208. By repeating this operation, the stripe region 32 is irradiated in order. After completing scanning of one stripe region 32, the irradiation region 34 is moved to the next stripe region 32 by moving the stage 105 and/or by collectively deflecting all the multiple primary electron beams 20 by the deflector 208. As described above, by irradiation with each primary electron beam 8, the scanning operation per sub-irradiation region 29 and acquisition of a secondary electron image are performed. By combining these secondary electron images of respective sub-irradiation regions 29, a secondary electron image of the rectangular region 33, a secondary electron image of the stripe region 32, or a secondary electron image of the chip 332 is configured. When an image comparison is actually performed, the sub-irradiation region 29 in each rectangular region 33 is further divided into a plurality of frame regions 30, and then, a comparison is performed with respect to a frame image 31 of each frame region 30. FIG. 4 shows the case of dividing the sub-irradiation region 29, which is scanned with one primary electron beam 8, into four frame regions 30 by halving it in the x and y directions, for example.

As described above, the image acquisition mechanism 150 proceeds with a scanning operation per stripe region 32. The multiple secondary electron beams 300 emitted because the substrate 101 is irradiated with the multiple primary electron beams 20 are detected by the multi-detector 222. A reflected electron may be included in the detected multiple secondary electron beams 300. Alternatively, it is also acceptable that a reflected electron is separated during moving in the secondary electron optical system 152 not to reach the multi-detector 222. Detection data (measured image data: secondary electron image data: inspection image data) on the secondary electron of each pixel in each sub-irradiation region 29, detected by the multi-detector 222, is output to the detection circuit 106 in order of measurement. In the detection circuit 106, the detection data in analog form is converted into digital data by an A-D converter (not shown), and stored in the chip pattern memory 123. Then, acquired measured image data is transmitted to the comparison circuit 108, together with information on each position from the position circuit 107.

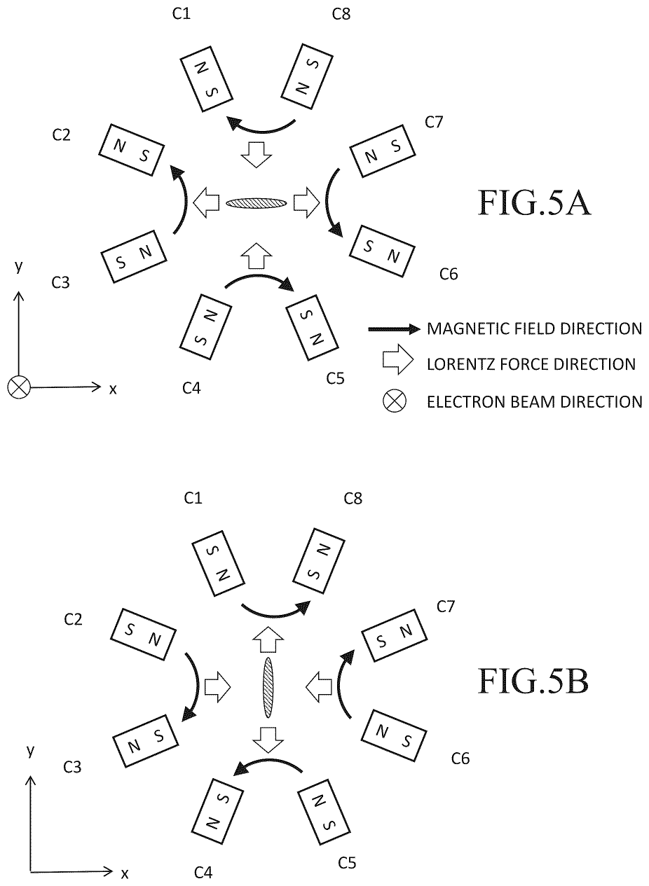

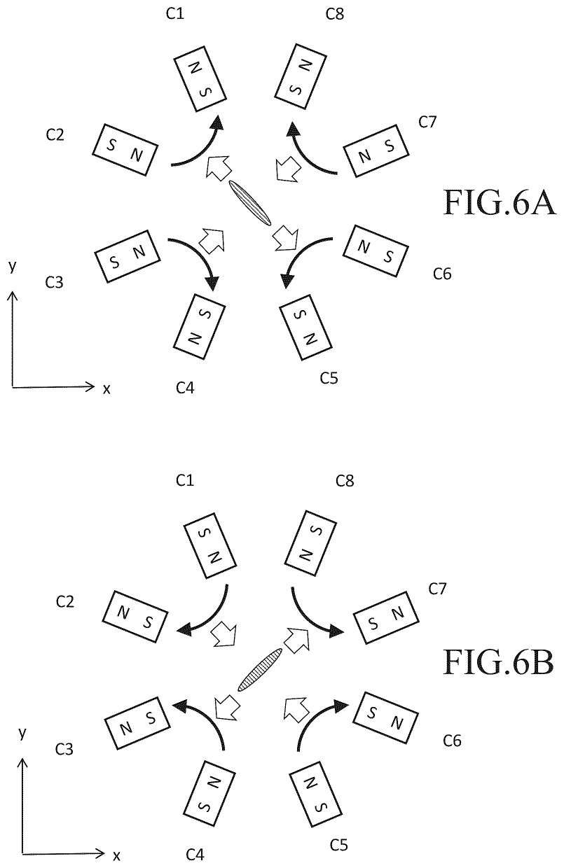

FIG. 5A is an illustration showing an example of the structure of a multipole corrector and an example of an excited state according to the first embodiment. FIG. 5B is an illustration showing an example of a structure of a multipole corrector and another example of an excited state according to the first embodiment. FIG. 6A is an illustration showing an example of the structure of a multipole corrector and another example of an excited state according to the first embodiment. FIG. 6B is an illustration showing an example of the structure of a multipole corrector and another example of an excited state according to the first embodiment. FIGS. 5A and 5B show the cases where forces are exerted in the x and y directions. FIGS. 6A and 6B show the cases where forces are exerted in the directions such that phases are rotated by 45° with respect to the x and y directions. FIG. 5B shows the case of an excitation in the opposite direction to that of FIG. 5A. FIG. 6B shows the case of an excitation in the opposite direction to that of FIG. 6A. In the examples of FIGS. 5A, 5B, 6A and 6B, eight magnetic poles (electromagnetic coils) are arranged as the multipole corrector 227. In the cases of FIGS. 5A, 5B, 6A, and 6B, opposing magnetic poles are controlled to mutually have the same polarity. In the examples of FIGS. 5A, 5B, 6A, and 6B, an electromagnetic coil C1 is arranged such that its phase is rotated leftward by 22.5° with respect to the y direction, and then, electromagnetic coils C2 to C8 whose phases are shifted from each other by 45° are arranged. FIGS. 5A, 5B, 6A and 6B show the cases where the multiple secondary electron beams 300 travel from front to backward in view of the page.

In the case of FIG. 5A, the electromagnetic coils C3, C4, C7, and C8 are arranged such that their N poles face the center, and the electromagnetic coils C1, C2, C5, and C6 are arranged such that their S poles face the center. Thereby, to the multiple secondary electron beams 300 passing through the center portion of the multipole corrector 227, a pulling force is exerted in the opposite directions (−x and x directions (0° and 180° directions)) along the line connecting the intermediate position of the electromagnetic coils C2 and C3 and that of the electromagnetic coils C6 and C7, and a compression force is exerted in the opposite directions (−y and y directions (90° and 270° directions)) along the line connecting the intermediate position of the electromagnetic coils C8 and C1 and that of the electromagnetic coils C4 and C5. By this, the beam array distribution shape of the multiple secondary electron beams 300 can be corrected to expand in the x direction and shrink in the y direction.

If excitation is performed oppositely to the state of FIG. 5A, as shown in the example of FIG. 5B, the electromagnetic coils C3, C4, C7, and C8 are arranged such that their S poles face the center, and the electromagnetic coils C1, C2, C5, and C6 are arranged such that their N poles face the center. Thereby, to the multiple secondary electron beams 300 passing through the center portion of the multipole corrector 227, a compression force is exerted in the opposite directions (−x and x directions) along the line connecting the intermediate position of the electromagnetic coils C2 and C3 and that of the electromagnetic coils C6 and C7, and a pulling force is exerted in the opposite directions (−y and y directions) along the line connecting the intermediate position of the electromagnetic coils C8 and C1 and that of the electromagnetic coils C4 and C5. By this, the beam array distribution shape of the multiple secondary electron beams 300 can be corrected to expand in the y direction and shrink in the x direction.

In the case of FIG. 6A, the electromagnetic coils C2, C3, C6, and C7 are arranged such that their N poles face the center, and the electromagnetic coils C1, C4, C5, and C8 are arranged such that their S poles face the center. Thereby, to the multiple secondary electron beams 300 passing through the center portion of the multipole corrector 227, a pulling force is exerted in the opposite directions (135° and 315° directions) along the line connecting the intermediate position of the electromagnetic coils C1 and C2 and that of the electromagnetic coils C5 and C6, and a compression force is exerted in the opposite directions (45° and 225° directions) along the line connecting the intermediate position of the electromagnetic coils C3 and C4 and that of the electromagnetic coils C7 and C8. By this, the beam array distribution shape of the multiple secondary electron beams 300 can be corrected to expand in 135° direction and shrink in 45° direction.

If excitation is performed oppositely to the state of FIG. 6A, as shown in the example of FIG. 6B, the electromagnetic coils C2, C3, C6, and C7 are arranged such that their S poles face the center, and the electromagnetic coils C1, C4, C5, and C8 are arranged such that their N poles face the center. Thereby, to the multiple secondary electron beams 300 passing through the center portion of the multipole corrector 227, a compression force is exerted in the opposite directions (135° and 315° directions) along the line connecting the intermediate position of the electromagnetic coils C1 and C2 and that of the electromagnetic coils C5 and C6, and a pulling force is exerted in the opposite directions (45° and 225° directions) along the line connecting the intermediate position of the electromagnetic coils C3 and C4 and that of the electromagnetic coils C7 and C8. By this, the beam array distribution shape of the multiple secondary electron beams 300 can be corrected to expand in 45° and 225° directions and shrink in 135° and 315° directions.

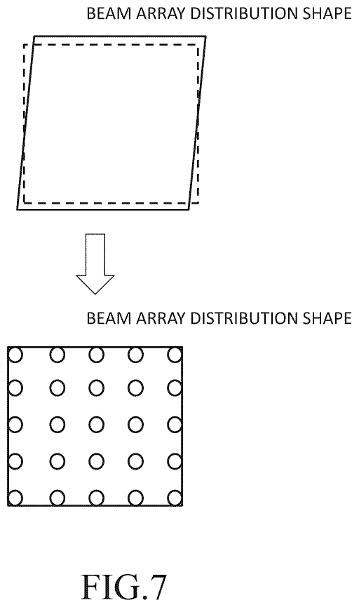

FIG. 7 is an illustration showing an example of a beam array distribution shape according to the first embodiment. By adjusting each magnetic pole of the multipole corrector 227, as shown in FIG. 7, the beam array distribution shape obliquely distorted can be close to a quadrangle, for example.

As described above, since the multiple primary electron beams 20 are scanned (primary scanning) over the inside of the sub-irradiation region 29, the emission position of each secondary electron beam changes every second in the sub-irradiation region 29. Therefore, if left as it is, each secondary electron beam is projected onto a position deviated from a corresponding detection element of the multi-detector 222. Then, the deflector 226 collectively deflects the multiple secondary electron beams 300 so that each secondary electron beam whose emission position has changed as described above may be applied to a corresponding detection region of the multi-detector 222. Specifically, in order to make each secondary electron beam irradiate a corresponding detection region of the multi-detector 222, the deflector 226 performs a deflection (secondary scanning) for swinging back (cancelling) a position movement of the multiple secondary electron beams caused by the change of the emission position.

However, if the beam array shape is corrected by the multipole corrector 227 during the period between the primary scanning by the deflector 209 and the secondary scanning by the deflector 226, there is a problem that errors occur at positions of multiple secondary electron beams having been swung back by the secondary scanning. Then, according to the first embodiment, the secondary scanning is performed including correcting such errors.

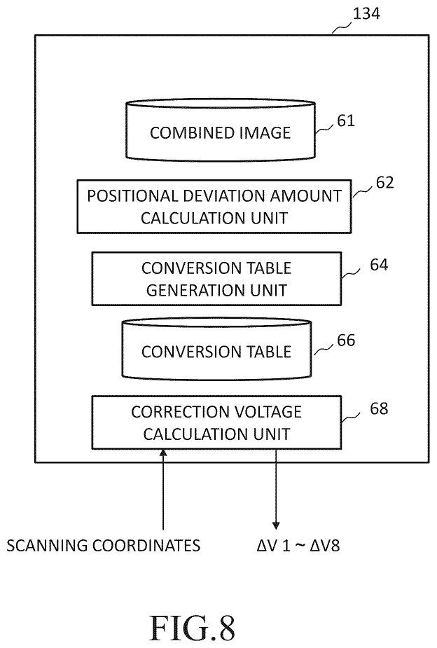

FIG. 8 is a diagram showing an example of the internal configuration of a deflection adjustment circuit according to the first embodiment. In FIG. 8, in the deflection adjustment circuit 134, there are arranged storage devices 61 and 66 such as magnetic disk drives, a positional deviation amount calculation unit 62, a conversion table generation unit 64, and a correction voltage calculation unit 68. Each of the “units” such as the positional deviation amount calculation unit 62, the conversion table generation unit 64, and the correction voltage calculation unit 68 includes processing circuitry. The processing circuitry includes, for example, an electric circuit, a computer, a processor, a circuit board, a quantum circuit, a semiconductor device, or the like. Common processing circuitry (the same processing circuitry), or different processing circuitry (separate processing circuitry) may be used for each of the “units”. Input data required in the positional deviation amount calculation unit 62, the conversion table generation unit 64, and the correction voltage calculation unit 68, and calculated results are stored in a memory (not shown) or in the memory 118 each time.

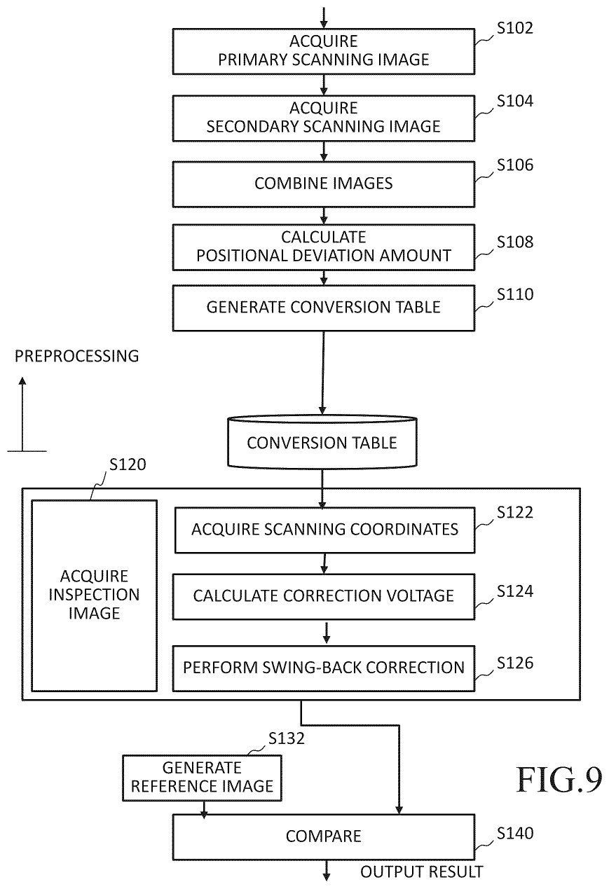

FIG. 9 is a flowchart showing main steps of an inspection method according to the first embodiment. In FIG. 9, the main steps of the inspection method of the first embodiment execute a series of steps: a primary scanning image acquisition step (S102), a secondary scanning image acquisition step (S104), an image combining step (S106), a positional deviation amount calculation step (S108), a conversion table generation step (S110), an inspection image acquisition step (S120), a scanning coordinate acquisition step (122), a correction voltage calculation step (S124), a swing-back correction step (S126), a reference image generation step (S132), and a comparison step (S140).

An image acquisition method of the first embodiment executes a series of steps: the primary scanning image acquisition step (S102), the secondary scanning image acquisition step (S104), the image combining step (S106), the positional deviation amount calculation step (S108), the conversion table generation step (S110), the inspection image acquisition step (S120), the scanning coordinate acquisition step (122), the correction voltage calculation step (S124), and the swing-back correction step (S126).

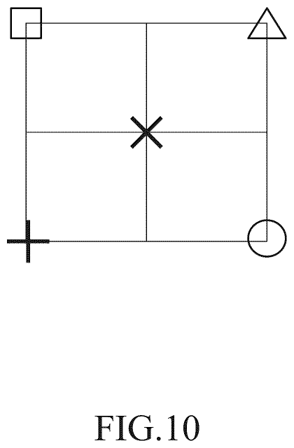

FIG. 10 is an illustration showing an example of a primary scanning region according to the first embodiment. FIG. 10 shows a deflection position of the center beam of the multiple primary electron beams 20, which are, for example, 5×5 beams, in the primary scanning region at the time of the primary scanning. In FIG. 10, the case where the multiple primary electron beams 20 are applied to the deflection center in the primary scanning region is denoted by the deflection position “x” of the center beam of the multiple primary electron beams 20. The case where the multiple primary electron beams 20 are deflected to the upper left corner portion in the primary scanning region is denoted by the deflection position “□” of the center beam of the multiple primary electron beams 20. The case where the multiple primary electron beams 20 are deflected to the upper right corner portion in the primary scanning region is denoted by the deflection position “Δ” of the center beam of the multiple primary electron beams 20. The case where the multiple primary electron beams 20 are deflected to the lower left corner portion in the primary scanning region is denoted by the deflection position “+” of the center beam of the multiple primary electron beams 20. The case where the multiple primary electron beams 20 are deflected to the lower right corner portion in the primary scanning region is denoted by the deflection position “∘” of the center beam of the multiple primary electron beams 20.

In the primary scanning image acquisition step (S102), in the state where the multipole corrector 227 has been excited to correct the beam array distribution shape of the multiple secondary electron beams 300, the deflector 209 deflects the multiple primary electron beams 20 to respective positions in the primary scanning region. For example, 5×5 respective deflection positions including peripheral positions and the deflection center are set in the primary scanning region. Then, for each deflection position, in the state where the multiple primary electron beams 20 have been deflected to the deflection positions concerned, the multiple secondary electron beams 300 for which a swing-back deflection has not been performed are detected. In other words, is detected the position of each beam of the multiple secondary electron beams 300 at respective deflection positions in the case of the primary scanning being executed without performing the secondary scanning (swing-back deflection).

Here, it is preferable to use, instead of the multi-detector 222, another electron beam detector (electron beam camera) whose number of detection elements is greater than that of the multiple secondary electron beams. For example, a detector whose number of detection elements is 2000×2000 is used. In the case where the number of a plurality of detection elements of the multi-detector 222 is the same as the number of the multiple secondary electron beams 300, when the multiple primary electron beams 20 are deflected to positions except for the deflection center of the primary scanning region, if in the state of a swing-back deflection being not performed, some (a portion) of the multiple secondary electron beams 300 are displaced out of the detection surface of the multi-detector 222. Therefore, by using, instead of the multi-detector 222, another electron beam detector (electron beam camera) whose number of detection elements is greater than the number of the multiple secondary electron beams, it becomes possible to detect all of the multiple secondary electron beams 300. Then, in order to detect the position of each secondary beam as an image of the detector aperture array substrate 228, the secondary scanning of a predetermined scan range is executed apart from a swing-back deflection originally performed. In the inspection image acquisition step (S120) to be described later, the multi-detector 222 is used instead of the another electron beam detector (electron beam camera). In other words, at the time of acquiring data for correction, the electron beam camera whose number of detection elements is greater than the number of the multiple secondary electron beams 300 is used, and at the time of the operation (inspection) of the apparatus, the electron beam camera is exchanged for the multi-detector 222 whose number of detection elements is the same as or a little greater than the number of the multiple secondary electron beams 300.

However, it is also acceptable to use the multi-detector 222 in the primary scanning image acquisition step (S102). Since, in the case of using the multi-detector 222, a portion of the multiple secondary electron beams 300 are displaced out of the detection surface, the multi-detector 222 is arranged on a drive stage (not shown) which can move in a planar direction (XY directions) of the second beam system. Then, the multi-detector 222 is moved in accordance with the deflection direction of the multiple primary electron beams 20 in order to detect the multiple secondary electron beams. Thereby, all of the multiple secondary electron beams 300 can be detected. Thus, the position of each secondary electron beam can be acquired. Detection data (measured image data: secondary electron image data: inspection image data) on a secondary electron is output to the detection circuit 106 in order of measurement. In the detection circuit 106, the detection data in analog form is converted into digital data by an A-D converter (not shown), and stored in the chip pattern memory 123.

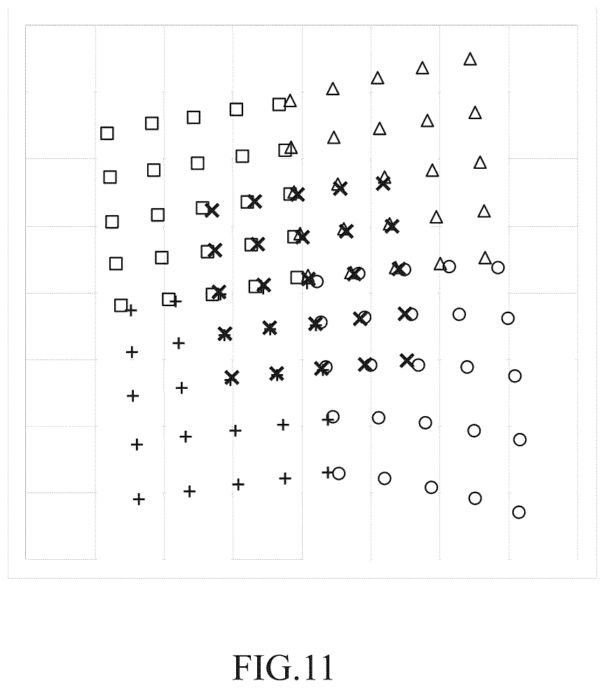

FIG. 11 is an illustration showing an example of an image of a beam detection position at each deflection position in the primary scanning region according to the first embodiment. FIG. 11 shows an example of the detection position of each beam of the multiple secondary electron beams 300 acquired in the primary scanning image acquisition step (S102) in which a deflection to a position used in the primary scanning without executing the secondary scanning is performed. As shown in FIG. 11, in the case where 5×5 multiple primary electron beams 20 are deflected to deflection positions each denoted by “∘” in the primary scanning, it turns out that detection positions of corresponding 5×5 multiple secondary electron beams 300 are largely distorted at the lower right side, for example. This is because of being influenced by correction of the beam array distribution shape by the multipole corrector 227.

In the secondary scanning image acquisition step (S104), in the state where the multipole corrector 227 has been excited to correct the beam array distribution shape of the multiple secondary electron beams 300, the multiple primary electron beams 20 are deflected to the deflection center of the primary scanning region. Then, a swing-back deflection of emitted multiple secondary electron beams 300 is performed by the deflector 226 of the second beam system. In other words, a swing-back deflection is performed for swinging back the position movement of the multiple secondary electron beams 300 in the case of deflecting the multiple primary electron beams 20 to respective 5×5 deflection positions in the primary scanning region. In other words, is detected the position of each beam of the multiple secondary electron beams 300 at respective deflection positions in the case of executing the secondary scanning without performing the primary scanning.

For example, deflection is performed so that emitted multiple secondary electron beams 300, which were emitted when the multiple primary electron beams 20 were applied to the center of the primary scanning region, may be detected by a corresponding detection element of the multi-detector 222. Then, regarding the deflection position of the multiple secondary electron beams 300 mentioned above as the center of the secondary scanning region, a swing-back deflection is performed for swinging back the moved position of the multiple secondary electron beams 300 based on respective deflection positions in the primary scanning region. Thereby, positions of the multiple secondary electron beams 300 at respective, for example, 5×5 positions in the secondary scanning region can be detected.

Here, it is preferable to use, instead of the multi-detector 222, another electron beam detector (electron beam camera) whose number of detection elements is greater than that of the multiple secondary electron beams. For example, a detector whose number of detection elements is 2000×2000 is used. In the state where deflection for the secondary scanning is performed without performing the primary scanning, some (a portion) of the multiple secondary electron beams 300 are displaced out of the detection surface of the multi-detector 222. Then, by using another electron beam detector whose number of detection elements is greater than the number of the multiple secondary electron beams, it becomes possible to detect all of the multiple secondary electron beams 300. In the inspection image acquisition step (S120) to be described later, the multi-detector 222 is used instead of the another electron beam detector (electron beam camera).

However, it is also acceptable to use the multi-detector 222 in the secondary scanning image acquisition step (S104). Since, in the case of using the multi-detector 222, a portion of the multiple secondary electron beams 300 are displaced out of the detection surface, the multi-detector 222 is arranged on a drive stage (not shown) which can move in a planar direction (XY directions) of the second beam system. Then, the multi-detector 222 is moved in accordance with the deflection direction of the multiple primary electron beams 20 in order to detect the multiple secondary electron beams. Thereby, all of the multiple secondary electron beams 300 can be detected. Thus, the detection position of each beam of the multiple secondary electron beams 300 at each position of the secondary scanning can be acquired. Detection data (measured image data: secondary electron image data: inspection image data) on a secondary electron is output to the detection circuit 106 in order of measurement. In the detection circuit 106, the detection data in analog form is converted into digital data by an A-D converter (not shown), and stored in the chip pattern memory 123.

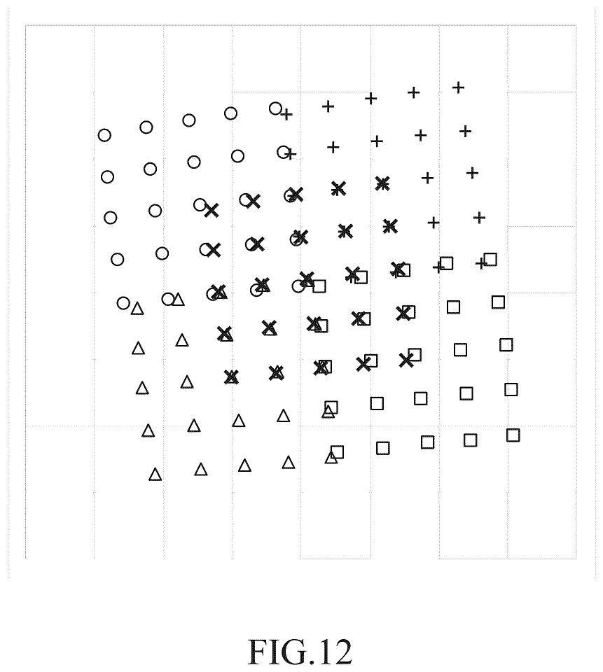

FIG. 12 is an illustration showing an example of an image of the beam detection position at each deflection position of the secondary scanning before performing a swing-back correction according to the first embodiment. FIG. 12 shows an example of a detection position of each beam of the multiple secondary electron beams 300 acquired in the secondary scanning image acquisition step (S104) in which a swing-back deflection to a position used in the secondary scanning without executing the primary scanning is performed. In FIG. 12, it is turned out that no large distortion has occurred with respect to each beam. Since a swing-back deflection is performed in the secondary scanning, each beam of the multiple secondary electron beams 300 which is corresponding to that of the multiple secondary electron beams 300 shown in FIG. 11 is detected at the position opposite to that in FIG. 11.

In the image combining step (S106), the image combining circuit 138 (an example of a combined position distribution generation unit) generates a combined position distribution by combining a detection position distribution of the multiple secondary electron beams 300 which is generated due to deflection of the multiple primary electron beams 20 occurred along with the primary scanning, and a detection position distribution of the multiple secondary electron beams 300 which is generated due to deflection of the multiple secondary electron beams 300 for cancelling out the position movement of the multiple secondary electron beams 300 having moved along with scanning the multiple primary electron beams 20. Specifically, the image combining circuit 138 combines an image of the detection position of each beam of the multiple secondary electron beams 300 obtained by executing the primary scanning without performing the secondary scanning, and an image of the detection position of each beam of the multiple secondary electron beams 300 obtained by executing the secondary scanning without performing the primary scanning.

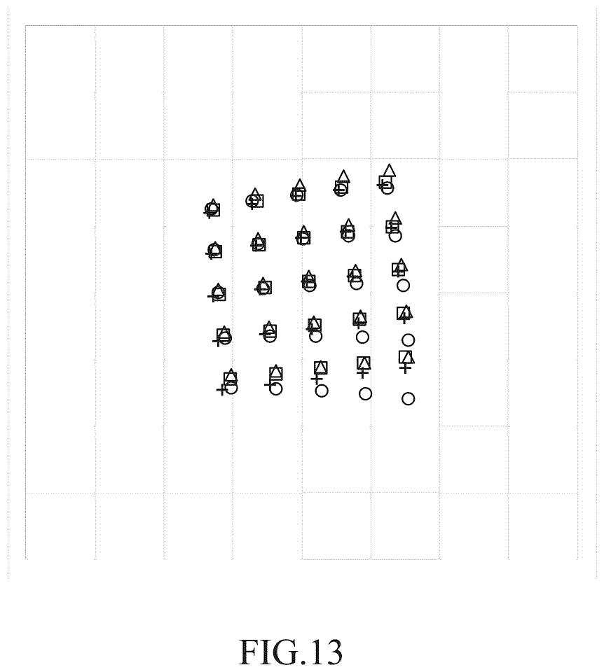

FIG. 13 is an illustration showing an example of a combined image acquired before a swing-back correction according to the first embodiment. FIG. 13 shows a combined image obtained by combining an image of the detection position at the deflection position of each beam of the multiple secondary electron beams 300 acquired by executing the primary scanning without performing the secondary scanning shown in FIG. 11, and an image of the detection position at the deflection position of each beam of the multiple secondary electron beams 300 acquired by executing the secondary scanning without performing the primary scanning shown in FIG. 12. In the case of FIG. 13, it turns out, with respect to each beam of the multiple secondary electron beams 300 after the combining, that distortion largely remains at the lower right positions each denoted by “∘” after performing a swing-back deflection. The generated combined image is output to the deflection adjustment circuit 134, and then, stored in the storage device 61 in the deflection adjustment circuit 134.

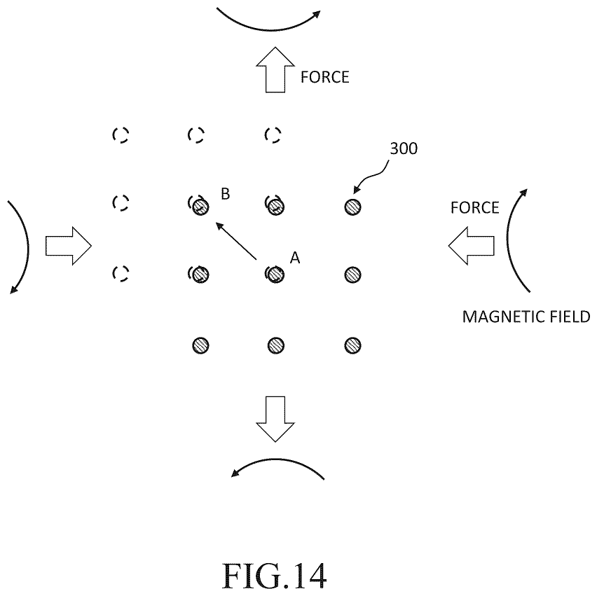

FIG. 14 is an illustration explaining an influence of correcting a beam array distribution shape according to the first embodiment. FIG. 14 shows the case where, for example, a compression force in the x direction and a pulling force in the y direction are exerted on the multiple secondary electron beams 300 by the multipole corrector 227. In that case, if the center of the primary scanning region is irradiated with the multiple primary electron beams 20, the position where a corresponding beam of the multiple secondary electron beams 300 (solid line) passes through the multipole corrector 227 is represented as “A”. If the multiple primary electron beams 20 are deflected, for example, to the upper left corner in the primary scanning region, the position where a corresponding beam of the multiple secondary electron beams 300 (dotted line) passes through the multipole corrector 227 is represented as “B”. Thus, the position of the multiple secondary electron beams 300 passing through the multipole corrector 227 varies depending on the deflection position deflected by the primary scanning. Therefore, the influence on each secondary electron beam from the magnetic field generated by the multipole corrector 227 varies depending on each position of the primary scanning. As a result, according to the position of the primary scanning, a difference occurs in correction results of the beam array distribution shape. Accordingly, it is difficult to eliminate an error generated in correcting the beam array distribution shape by the multipole corrector 227 by just performing, in the secondary scanning, a swing-back deflection of the primary scanning. Therefore, according to the first embodiment, is calculated the amount of a positional deviation being generated in the case of correcting a beam array distribution shape and being dependent on each deflection position of the primary scanning.

In the positional deviation amount calculation step (S108), the positional deviation amount calculation unit 62 calculates an amount of positional deviation (error), generated in correcting a beam array distribution shape, between a combined position distribution and a design position distribution. The amount of positional deviation is calculated at each deflection position in the primary scanning region. For example, the vector (direction and size) of the maximum positional deviation amount is calculated at each deflection position. Alternatively, a mean square of a positional deviation amount of each beam may be calculated. It is acceptable that such a positional deviation amount (distortion) includes an error component of the trajectory of the multiple secondary electron beams 300 generated by the primary scanning with the multiple primary electron beams 20.

In the conversion table generation step (S110), the conversion table generation unit 64 generates a conversion table which shows a relationship between each deflection position of the primary scanning and a correction potential for correcting an amount of positional deviation occurred between a combined position distribution and a design position distribution.

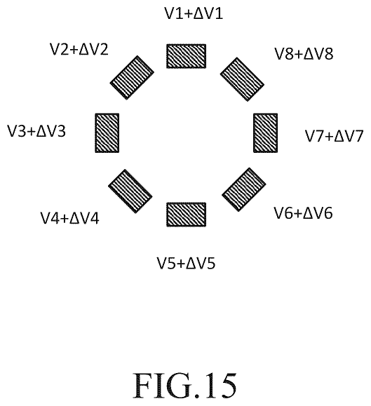

FIG. 15 is an illustration explaining each electrode of a deflector and an electric potential applied to the each electrode in the secondary system according to the first embodiment. In FIG. 15, the deflector 226 of the secondary system is configured by eight electrodes, for example. To the eight electrodes 1 to 8, electric potentials V1 to V8 being swing-back deflection amounts of the primary scanning are individually applied. Furthermore, correction potentials ΔV1 to ΔV8 for correcting the positional deviation amounts each between a combined position distribution and a design position distribution are individually added and applied.

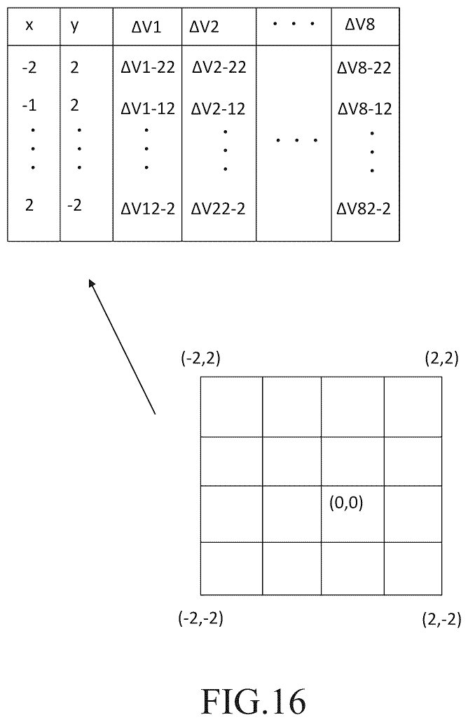

FIG. 16 is a diagram showing an example of a conversion table according to the first embodiment. In the conversion table of FIG. 16, deflection position coordinates x and y in the primary scanning region, and correction potentials ΔV1 to ΔV8 each corresponding to each deflection position are relatedly defined. For example, at the deflection position coordinates (−2, 2), a correction potential ΔV1-22 of the electrode 1, a correction potential ΔV2-22 of the electrode 2, . . . and a correction potential ΔV8-22 of the electrode 8 are defined. k of ΔVkij indicates an electrode number. i indicates the x-coordinate of a deflection position in the primary scanning region, and j indicates the y-coordinate of the deflection position in the primary scanning region. The deflection position coordinates x and y are defined with respect to, for example, respective 5×5 deflection positions in the primary scanning region. In the case of FIG. 16, the deflection center of the primary scanning is indicated as coordinates (0, 0). It is preferable to define a combination of correction potentials of respective electrodes so that deflection to a position where the positional deviation amount of the multiple secondary electron beams 300 having been swung-back is the smallest may be performed. For example, there is defined a combination of correction potentials of respective electrodes such that a mean square of a positional deviation amount of each beam becomes the minimum. Alternatively, there is defined a combination of correction potentials of respective electrodes so that the largest positional deviation amount in positional deviation amounts of respective beams may become the smallest value (amount). The generated conversion table is stored in the storage device 66. A combination of correction potentials of respective electrodes is calculated so that the multiple secondary electron beams 300 may be deflected to a position where a positional deviation has been corrected. Such a correction potential is preferably obtained by an experiment or simulation. Alternatively, it may be obtained by calculation using an equation.

The image of the detection position of each beam of the multiple secondary electron beams 300, acquired in the primary scanning image acquisition step (S102) in which a deflection to the position used in the primary scanning without executing the secondary scanning is performed, is the same as that of FIG. 11.

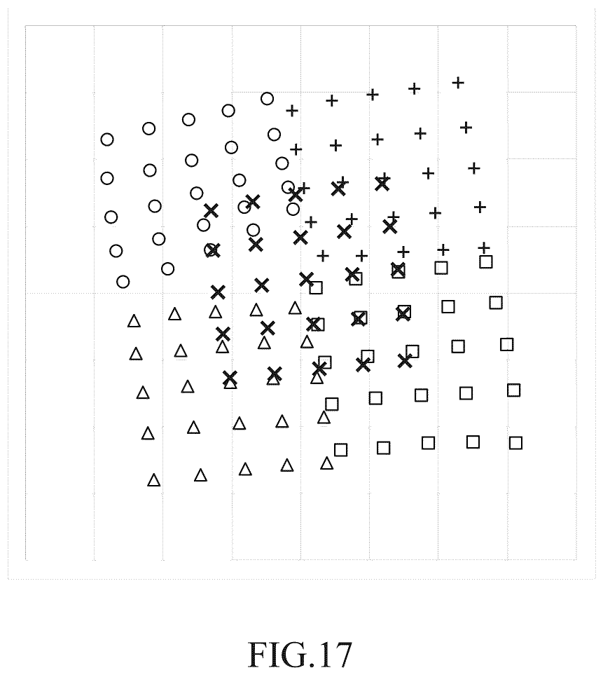

FIG. 17 is an illustration showing an example of an image of a beam detection position at each deflection position of the secondary scanning after a swing-back correction according to the first embodiment. FIG. 17 shows an example of a detection position of each beam of the multiple secondary electron beams 300 acquired in the secondary scanning image acquisition step (S104) in which a swing-back deflection to the position used in the secondary scanning without executing the primary scanning is performed. Further, FIG. 17 shows an example of a detection position of each beam of the multiple secondary electron beams 300 in the case where a correction potential is applied to each electrode of the deflector 226 so that a positional deviation occurred along with correction of a beam array distribution shape may be corrected. The detection position in FIG. 17 differs from that of each beam of the multiple secondary electron beams 300 before performing a correction shown in FIG. 12. For example, it turn out, since distortion occurred at the deflection positions at the lower right side, each denoted by “o”, has been corrected, that detection positions of the multiple secondary electron beams 300 are deviated by the amount of the distortion correction.

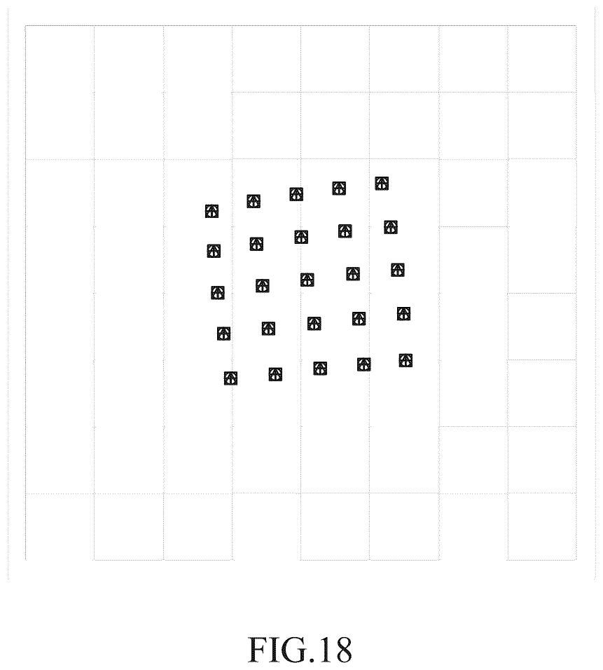

FIG. 18 is an illustration showing an example of a combined image acquired after a swing-back correction according to the first embodiment. FIG. 18 shows a combined image obtained by combining an image of the detection position at the deflection position of each beam of the multiple secondary electron beams 300 acquired by executing the primary scanning without performing the secondary scanning shown in FIG. 11, and an image of the detection position at the deflection position of each beam of the multiple secondary electron beams 300 acquired by executing the secondary scanning without performing the primary scanning shown in FIG. 17. In the case of FIG. 18, it turns out, with respect to each beam of the multiple secondary electron beams 300 after the combining, that the distortion occurred because of correcting the beam array distribution shape by the multipole corrector 227 has been corrected after the swing-back deflection.

In the conversion table described above, deflection position coordinates x and y in the primary scanning region, and correction potentials ΔV1 to ΔV8 each corresponding to each deflection position are relatedly defined for one beam array distribution shape correction condition. However, it is not limited thereto. It is also preferable, for a plurality of beam array distribution shape correction conditions, that deflection position coordinates x and y in the primary scanning region, and correction potentials ΔV1 to ΔV8 each corresponding to each deflection position are relatively defined for each of the plurality of beam array distribution shape correction conditions.

After completing the preprocessing described above, an image of the inspection substrate is acquired.

In the inspection image acquisition step (S120), the image acquisition mechanism 150 irradiates the substrate 101 with the multiple primary electron beams 20 in order to acquire a secondary electron image of the substrate 101 using the multiple secondary electron beams 300 emitted from the substrate. In this process, under the control of the deflection control circuit 128, the deflector 208 (the first deflector) scans the multiple primary electron beams 20 over the substrate 101 (target object) by deflecting them.

In the scanning coordinate acquisition step (122), the correction voltage calculation unit 68 acquires (inputs) coordinates of a deflection position to be next deflected in the primary scanning by being synchronized with the deflection control circuit 128.

In the correction voltage calculation step (S124), by being synchronized with the deflection control circuit 128, the correction voltage calculation unit 68 calculates a correction potential of each electrode of the deflector 226 at the next deflection position based on the deflection position coordinates to be next deflected in the primary scanning. The correction potential of each electrode is calculated with reference to the conversion table. The correction potential of each electrode can be calculated, by a linear interpolation, at the position between deflection positions defined in the conversion table. The calculated correction potential of each electrode is output to the deflection control circuit 128.

When desired positions on the substrate 101 are irradiated with the multiple primary electron beams 20, a flux of secondary electrons (multiple secondary electron beams 300), including reflected electrons, each corresponding to each beam of the multiple primary electron beams 20 is emitted from the substrate 101 due to the irradiation with the multiple primary electron beams 20.

The multiple secondary electron beams 300 emitted from the substrate 101 travel to the E×B separator 214 through the electromagnetic lens 207. Then, the multiple secondary electron beams 300 are separated from the trajectory of the multiple primary electron beams 20 by the E×B separator 214, further bent by the deflector 218, and travel to the multipole corrector 227. The multipole corrector 227 (corrector) corrects the beam array distribution shape of the passing multiple secondary electron beams 300. The corrected multiple secondary electron beams 300 travel to the deflector 226.

In the swing-back correction step (S126), the deflection control circuit 128 superimposes a correction voltage, which corrects an error between a combined position distribution and a design position distribution, on a deflection voltage. Specifically, the deflection control circuit 128 superimposes deflection potentials V1 to V8, which cancel out the position movement of the multiple secondary electron beams 300 having moved along with scanning the multiple primary electron beams 20, on correction potentials ΔV1 to ΔV8, which correct a distortion being generated due to correcting the beam array distribution shape of the multiple secondary electron beams 300 and being dependent on a deflection amount (deflection position of the primary scanning) for scanning. Then, the deflection control circuit 128 performs controlling to apply a superimposed potential to the deflector 226. Under the control of the deflection control circuit 128, the deflector 226 (the second deflector) deflects multiple secondary electron beams which are acquired by correcting the beam array distribution shape of the multiple secondary electron beams 300. More specifically, an electric potential obtained by adding a deflection potential V1 for swing-back deflection and a correction potential ΔV1 is applied to the electrode 1 of the deflector 226. Another electric potential obtained by adding a deflection potential V2 for swing-back deflection and a correction potential ΔV2 is applied to the electrode 2 of the deflector 226. Similarly henceforth, superposition potentials are individually added to respective electrodes. That is, to the electrode 8 of the deflector 226, an electric potential obtained by adding a deflection potential V8 for swing-back deflection and a correction potential ΔV8 is applied. Thereby, the deflector 226 dynamically corrects a distortion of the multiple secondary electron beams 300 being generated due to correcting the beam array distribution shape of the multiple secondary electron beams 300 and being dependent on a scanning position (deflection position of the primary scanning) of scanning with the multiple primary electron beams 20.

The multiple secondary electron beams 300 deflected by the deflector 226 are detected by the multi-detector 222. Then, the multi-detector 222 outputs detection image data. Thereby, a secondary electron image of the substrate 101 is acquired.

As described above, the image acquisition mechanism 150 proceeds with a scanning operation per stripe region 32. A reflected electron may be included in the detected multiple secondary electron beams 300. Alternatively, it is also acceptable that a reflected electron is separated during moving in the secondary electron optical system 152 not to reach the multi-detector 222. Detection data (measured image data: secondary electron image data: inspection image data) on the secondary electron of each pixel in each sub-irradiation region 29, detected by the multi-detector 222, is output to the detection circuit 106 in order of measurement. In the detection circuit 106, the detection data in analog form is converted into digital data by an A-D converter (not shown), and stored in the chip pattern memory 123. Then, acquired measured image data is transmitted to the comparison circuit 108, together with information on each position from the position circuit 107.

As the image acquisition operation described above, a step-and-repeat operation may be performed which irradiates the substrate 101 with the multiple primary electron beams 20 in the state where the stage 105 is stopped, and which moves the position after finishing the scanning operation. Alternatively, it is also preferable to irradiate the substrate 101 with the multiple primary electron beams 20 while continuously moving the stage 105. When the multiple primary electron beams 20 irradiate the substrate 101 while the stage 105 is continuously moving, the main deflector 208 executes a tracking operation by performing collective deflection so that the irradiation position of the multiple primary electron beams 20 may follow the movement of the stage 105. Therefore, the emission position of the multiple secondary electron beams 300 changes every second with respect to the trajectory central axis of the multiple primary electron beams 20. Further, it is preferable for the deflector 226 to collectively deflect the multiple secondary electron beams 300 so that each secondary electron beam whose emission position has changed due to the tracking operation may be applied to a corresponding detection region of the multi-detector 222. In other words, it is sufficient to set a deflection potential of swing-back deflection such that deflection is performed including a position movement amount of a secondary electron beam due to the tracking operation.

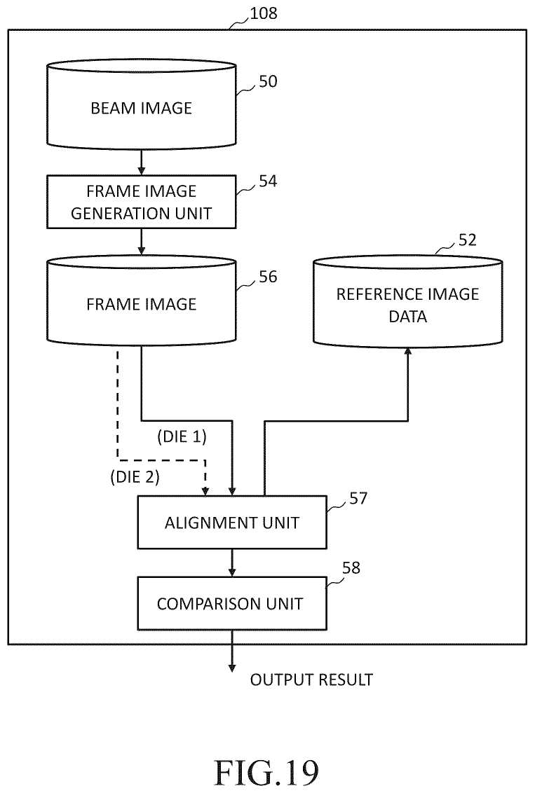

FIG. 19 is a diagram showing an example of the internal configuration of a comparison circuit according to the first embodiment. In FIG. 19, storage devices 50, 52 and 56, such as magnetic disk drives, a frame image generation unit 54, an alignment unit 57, and a comparison unit 58 are arranged in the comparison circuit 108. Each of the “units” such as the frame image generation unit 54, the alignment unit 57 and the comparison unit 58 includes processing circuitry. The processing circuitry includes an electric circuit, a computer, a processor, a circuit board, a quantum circuit, a semiconductor device, or the like. Further, common processing circuitry (same processing circuitry), or different processing circuitry (separate processing circuitry) may be used for each of the “units”. Input data required in the frame image generation unit 54, the alignment unit 57 and the comparison unit 58, or a calculated result is stored in a memory (not shown) or in the memory 118 each time.

Measured image data (beam image) transmitted into the comparison circuit 108 is stored in the storage device 50.

The frame image generation unit 54 generates the frame image 31 of each of a plurality of frame regions 30 obtained by further dividing image data of the sub-irradiation region 29 acquired by scanning each primary electron beam 8. The frame region 30 is used as a unit region of an inspection image to be inspected. In order to prevent missing an image, it is preferable that the margin region of each frame region 30 overlaps with each other. The generated frame image 31 is stored in the storage device 56.

In the reference image generation step (S132), the reference image generation circuit 112 generates, for each frame region 30, a reference image corresponding to the frame image 31, based on design data serving as a basis of a plurality of figure patterns formed on the substrate 101. Specifically, it operates as follows: First, design pattern data is read from the storage device 109 through the control computer 110, and each figure pattern defined by the read design pattern data is converted into image data in binary or multiple values.

Basic figures defined by the design pattern data are, for example, rectangles (including squares) and triangles. For example, figure data which defines the shape, size, position, and the like of each pattern figure is stored by using information, such as coordinates (x, y) of the reference position of the figure, lengths of sides of the figure, and a figure code serving as an identifier for identifying the figure type such as rectangles and triangles.

When design pattern data serving as the figure data is input to the reference image generation circuit 112, the data is expanded/developed into data for each figure, and then, a figure code, figure dimensions, and the like indicating the figure shape in each figure data are interpreted. Then, the reference image generation circuit 112 expands/develops each figure data to design pattern image data in binary or multiple values as a pattern to be arranged in squares in units of grids of predetermined quantization dimensions, and outputs the expanded/developed data. In other words, the reference image generation circuit 112 reads design data, calculates the occupancy of a figure in the design pattern, for each square region obtained by virtually dividing the inspection region into squares in units of predetermined dimensions, and outputs n-bit occupancy data. For example, it is preferable to set one square as one pixel. Assuming that one pixel has a resolution of ½⁸(= 1/256), the occupancy rate in each pixel is calculated by allocating sub-regions, each having 1/256 resolution, which correspond to the region of a figure arranged in the pixel. Then, it is generated as occupancy rate data of 8 bits. Such squares (inspection pixels) can be commensurate with pixels of measured data.

Next, the reference image generation circuit 112 performs filtering processing on design image data of a design pattern which is image data of a figure, using a predetermined filter function. Thereby, it becomes possible to match/fit the design image data being design side image data, whose image intensity (gray scale level) is represented by digital values, with image generation characteristics obtained by irradiation with the multiple primary electron beams 20. Image data for each pixel of a generated reference image is output to the comparison circuit 108. The reference image data transmitted into the comparison circuit 108 is stored in the storage device 52.

In the comparison step (S140), first, the alignment unit 57 reads the frame image 31 serving as an inspection image, and a reference image corresponding to the frame image 31 concerned, and provides alignment between both the images, based on units of sub-pixels smaller than units of pixels. For example, the alignment can be performed by a least squares method.

Then, the comparison unit 58 compares at least a portion of an acquired secondary electron image with a predetermined image. Here, a frame image obtained by further dividing the image of the sub-irradiation region 29 acquired for each beam is used. The comparison unit 58 compares, for each pixel, the frame image 31 and the reference image. The comparison unit 58 compares them, for each pixel, based on predetermined determination conditions in order to determine whether there is a defect such as a shape defect. For example, if a difference in gray scale level for each pixel is larger than a determination threshold Th, it is determined that there is a defect. Then, the comparison result is output. It may be output to the storage device 109 or the memory 118, or alternatively, output from the printer 119.

In the examples described above, the die-to-database inspection is performed. However, it is not limited thereto. A die-to-die inspection may be performed. In the case of the die-to-die inspection, alignment and comparison described above are carried out between the frame image 31 (die 1) to be inspected and another frame image 31 (die 2) (another example of a reference image) in which there is formed the same pattern as that of the frame image 31 to be inspected.

As described above, according to the first embodiment, in the case of correcting a beam array distribution shape of multiple secondary electron beams, it is possible to reduce an error occurred after a swing-back deflection of the multiple secondary electron beams executed for cancelling out a position movement of the multiple secondary electron beams having moved along with scanning multiple primary electron beams.

### Second Embodiment

In the first embodiment described above, the case is described where the multipole corrector 227 is arranged between the deflector 209 for performing the primary scanning and the deflector 226 for performing the secondary scanning (swing-back deflection). In a second embodiment, the case is described where the multipole corrector 227 is arranged on the trajectory after the secondary scanning (swing-back deflection). The contents of the second embodiment are the same as those of the first embodiment except what is specifically described below.

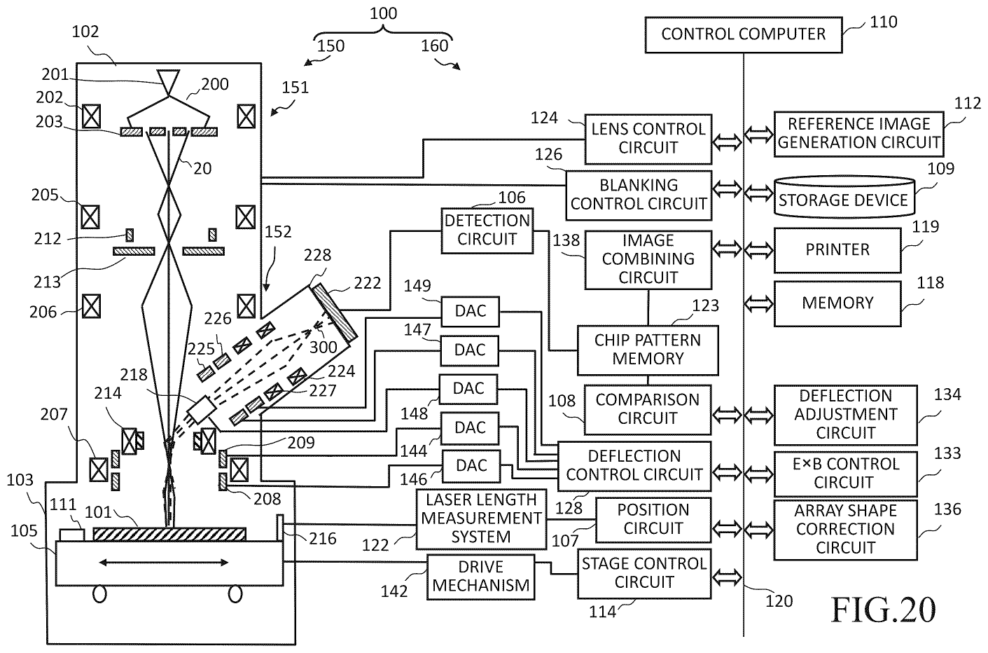

FIG. 20 is a diagram showing an example of the configuration of an inspection apparatus according to the second embodiment. FIG. 20 is the same as FIG. 1 except that the deflector 226 is arranged on the trajectory of the second beam system after the multiple secondary electron beams 300 having been separated therefrom by the E×B separator 214 and at the upstream side of the multipole corrector 227 on the trajectory of the second beam system. The contents of the main steps of the inspection method according to the second embodiment are the same as those of FIG. 9. In FIG. 20, the two-stage deflector composed of the deflectors 208 and 209 may be a single stage deflector (e.g., deflector 209). The two-stage deflector composed of the deflectors 225 and 226 may be a single stage deflector (e.g., deflector 226).

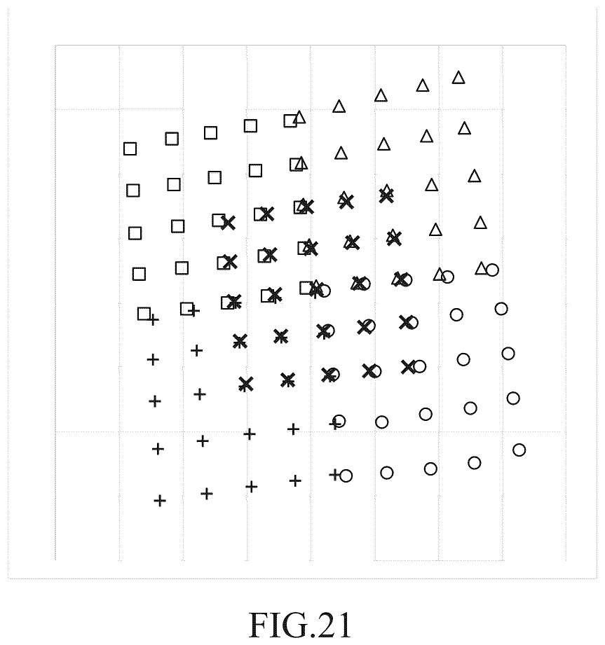

FIG. 21 is an illustration showing an example of an image of a beam detection position at each deflection position of the primary scanning before performing a swing-back correction according to the second embodiment. FIG. 12 shows, similarly to FIG. 11, an example of the detection position of each beam of the multiple secondary electron beams 300 acquired in the primary scanning image acquisition step (S102) in which a deflection to a position used in the primary scanning without executing the secondary scanning is performed.

According to the second embodiment, after the deflector 226 swings back the position movement of the multiple secondary electron beams 300 having moved along with the primary scanning, the multipole corrector 227 corrects the beam array distribution shape. Therefore, it does not occur that the position of the multiple secondary electron beams 300 passing through the multipole corrector 227 changes depending on a deflection position of the primary scanning. Thus, it is possible to avoid that the influence on each secondary electron beam from the magnetic field generated by the multipole corrector 227 changes depending on each deflection position of the primary scanning. Consequently, effects of correcting a beam array distribution shape at respective positions of the primary scanning can be mutually the same.

For this reason, in the example of FIG. 21 unlike the case of FIG. 11, no large distortion occurs. Therefore, in the configuration of the second embodiment, there is no need of adding a correction potential to each electrode of the deflector 226 such as performed in the first embodiment.

However, in the example of FIG. 21, it turns out that distortion, not large though, has occurred at the upper right side of beam deflection positions each denoted by “Δ” and at the lower left side of beam deflection positions each denoted by “+”, for example. This distortion is an error component of the trajectory of the multiple secondary electron beams 300 generated by the primary scanning with the multiple primary electron beams 20.

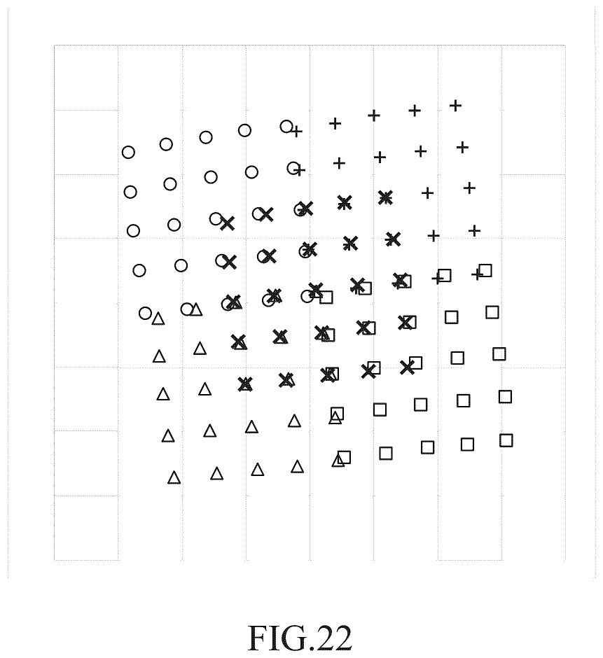

FIG. 22 is an illustration showing an example of an image of a beam detection position at each deflection position of the secondary scanning before performing a swing-back correction according to the second embodiment. FIG. 22 shows an example of a detection position of each beam of the multiple secondary electron beams 300 acquired in the secondary scanning image acquisition step (S104) in which a swing-back deflection to a position used in the secondary scanning without executing the primary scanning is performed. In FIG. 22, it is turned out that no large distortion has occurred with respect to each beam. Since a swing-back deflection is performed in the secondary scanning, each beam of the multiple secondary electron beams 300 which is corresponding to that of the multiple secondary electron beams 300 shown in FIG. 21 is detected at the position opposite to that in FIG. 21.

In the image combining step (S106), the image combining circuit 138 (an example of a combined position distribution generation unit) generates a combined position distribution by combining a detection position distribution of the multiple secondary electron beams 300 which is generated due to deflection of the multiple primary electron beams 20 occurred along with the primary scanning, and another detection position distribution of the multiple secondary electron beams 300 which is generated due to deflection of the multiple secondary electron beams 300 for cancelling out the position movement of the multiple secondary electron beams 300 having moved along with scanning the multiple primary electron beams 20. Specifically, the image combining circuit 138 combines an image of the detection position of each beam of the multiple secondary electron beams 300 obtained by executing the primary scanning without performing the secondary scanning, and an image of the detection position of each beam of the multiple secondary electron beams 300 obtained by executing the secondary scanning without performing the primary scanning.

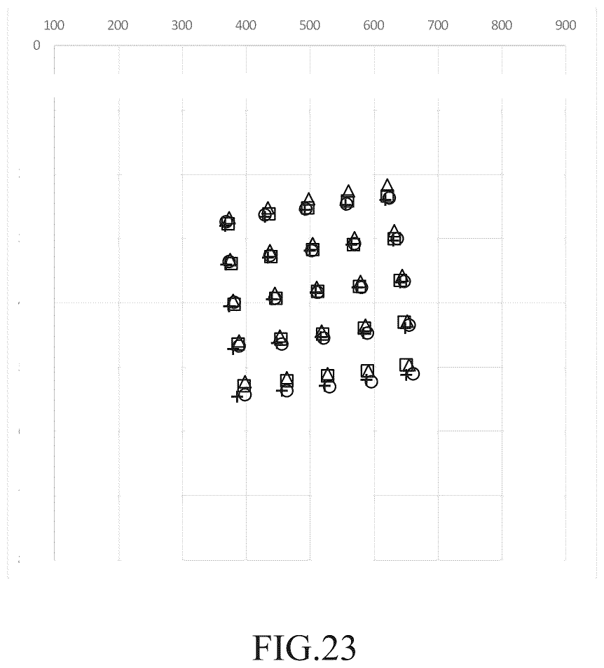

FIG. 23 is an illustration showing an example of a combined image acquired before a swing-back correction according to the second embodiment. FIG. 23 shows a combined image obtained by combining an image of the detection position at the deflection position of each beam of the multiple secondary electron beams 300 acquired by executing the primary scanning without performing the secondary scanning shown in FIG. 21, and an image of the detection position at the deflection position of each beam of the multiple secondary electron beams 300 acquired by executing the secondary scanning without performing the primary scanning shown in FIG. 22. In the case of FIG. 23, it turns out, with respect to each beam of the multiple secondary electron beams 300 after the combining, that distortions slightly remain, after performing a swing-back deflection, at the periphery at upper right beam deflection positions each denoted by “Δ”, and at the periphery at lower left beam deflection positions each denoted by “+”. The generated combined image is output to the deflection adjustment circuit 134, and then, stored in the storage device 61 in the deflection adjustment circuit 134.

As described above, these distortions are error components of the trajectory of the multiple secondary electron beams 300 generated by the primary scanning with the multiple primary electron beams 20. Then, according to the second embodiment, in order to obtain a higher accuracy, correction is performed for error components of the trajectory of the multiple secondary electron beams 300 generated by the primary scanning. The method of correction is the same as that of the first embodiment. Specifically, it operates as follows:

In the positional deviation amount calculation step (S108), the positional deviation amount calculation unit 62 calculates an amount of positional deviation (error), generated in correcting a beam array distribution shape, between a combined position distribution and a design position distribution. The amount of positional deviation is calculated at each deflection position in the primary scanning region. For example, the vector (direction and size) of the maximum positional deviation amount is calculated at each deflection position. Alternatively, a mean square of a positional deviation amount of each beam may be calculated. It is acceptable that such a positional deviation amount (distortion) includes an error component of the trajectory of the multiple secondary electron beams 300 generated by the primary scanning with the multiple primary electron beams 20.

In the conversion table generation step (S110), the conversion table generation unit 64 generates a conversion table which shows a relationship between each deflection position of the primary scanning and a correction potential for correcting an amount of positional deviation occurred between a combined position distribution and a design position distribution.

In the conversion table according to the second embodiment, as shown in FIG. 16, deflection position coordinates x and y in the primary scanning region, and correction potentials ΔV1 to ΔV8 each corresponding to each deflection position are relatedly defined.

The image of the detection position of each beam of the multiple secondary electron beams 300, acquired in the primary scanning image acquisition step (S102) in which a deflection to the position used in the primary scanning without executing the secondary scanning is performed, is the same as that of FIG. 21.

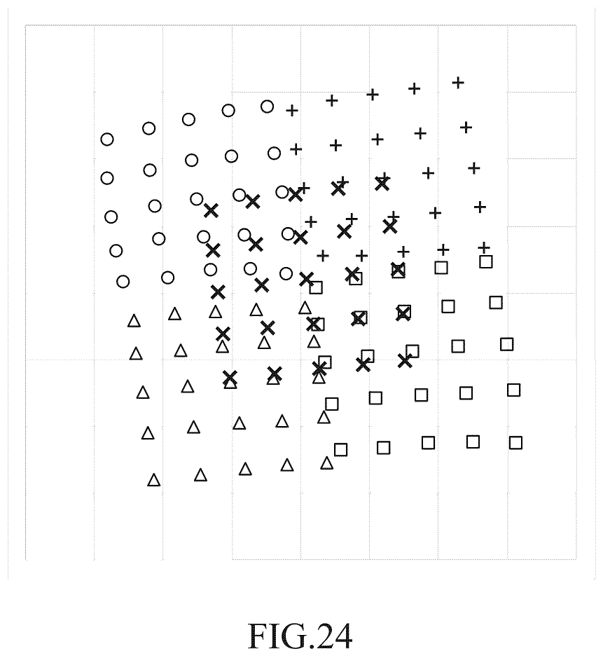

FIG. 24 is an illustration showing an example of an image of a beam detection position at each deflection position of the secondary scanning after a swing-back correction according to the second embodiment. FIG. 24 shows an example of a detection position of each beam of the multiple secondary electron beams 300 acquired in the secondary scanning image acquisition step (S104) in which a swing-back deflection to the position used in the secondary scanning without executing the primary scanning is performed. Further, FIG. 24 shows an example of a detection position of each beam of the multiple secondary electron beams 300 in the case where a correction potential is applied to each electrode of the deflector 226 so that an error component of the trajectory of the multiple secondary electron beams 300 generated by the primary scanning with the multiple primary electron beams 20 may be corrected. The detection position in FIG. 24 differs from that of each beam of the multiple secondary electron beams 300 before performing a correction shown in FIG. 22. For example, it turns out, since distortions occurred at the upper right beam deflection positions each denoted by “Δ” and at the lower left beam deflection positions each denoted by “+” have been corrected, that detection positions of the multiple secondary electron beams 300 are deviated by the amount of the distortion correction.

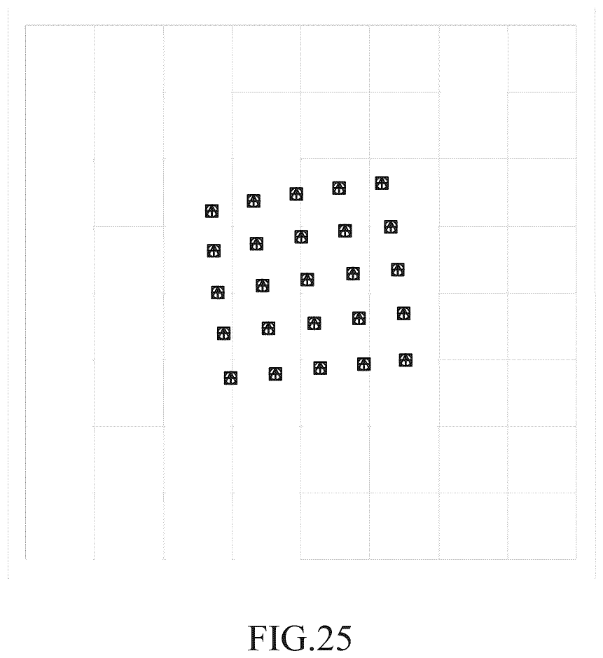

FIG. 25 is an illustration showing an example of a combined image acquired after a swing-back correction according to the second embodiment. FIG. 25 shows a combined image obtained by combining an image of the detection position at the deflection position of each beam of the multiple secondary electron beams 300 acquired by executing the primary scanning without performing the secondary scanning shown in FIG. 21, and an image of the detection position at the deflection position of each beam of the multiple secondary electron beams 300 acquired by executing the secondary scanning without performing the primary scanning shown in FIG. 24. In the case of FIG. 25, it turns out, with respect to each beam of the multiple secondary electron beams 300 after the combining, that the distortion occurred because of an error component of the trajectory of the multiple secondary electron beams 300 generated by the primary scanning with the multiple primary electron beams 20 has been corrected after the swing-back deflection.

After completing the preprocessing described above, an image of the inspection substrate is acquired. The contents of each step after the inspection image acquisition step (S120) are the same as those of the first embodiment. That is, the image acquisition mechanism 150 irradiates the substrate 101 with the multiple primary electron beams 20 in order to acquire a secondary electron image of the substrate 101 using the multiple secondary electron beams 300 emitted from the substrate. In this process, under the control of the deflection control circuit 128, the deflector 208 (the first deflector) scans the multiple primary electron beams 20 over the substrate 101 (target object) by deflecting them. The deflection control circuit 128 superimposes a correction voltage, which corrects an error between a combined position distribution and a design position distribution, on a deflection voltage. Then, the deflection control circuit 128 performs controlling to apply a superimposed potential to the deflector 226. Under the control of the deflection control circuit 128, the deflector 226 (the second deflector) deflects multiple secondary electron beams which are acquired by correcting the beam array distribution shape of the multiple secondary electron beams 300. Thereby, the deflector 226 dynamically corrects the distortion occurred because of an error component of the trajectory of the multiple secondary electron beams 300 generated by the primary scanning with the multiple primary electron beams 20.

The multipole corrector 227 corrects the beam array distribution shape of multiple secondary electron beams acquired by cancelling out the position movement of the multiple secondary electron beams 300 by deflecting the multiple secondary electron beams 300.

The multiple secondary electron beams 300 whose beam array distribution shape of the multiple secondary electron beams has been corrected is detected by the multi-detector 222. Then, the multi-detector 222 outputs detection image data. Thereby, a secondary electron image of the substrate 101 is acquired.

As described above, according to the second embodiment, it is possible to avoid generating an error in correcting the beam array distribution shape of multiple secondary electron beams, corrected depending on each deflection position of the primary scanning and corrected by the multipole corrector 227, and possible to correct an error component of the trajectory of the multiple secondary electron beams 300 generated by the primary scanning with the multiple primary electron beams 20.

In the Embodiments described above, the primary scanning is performed by the deflector 209, and the secondary scanning by the deflector 226. However, it is not limited thereto. The primary scanning may also preferably be performed by a set of the deflectors 208 and 209 (another example of the first deflector), and the secondary scanning by a set of the deflectors 225 and 226 (another example of the second deflector).

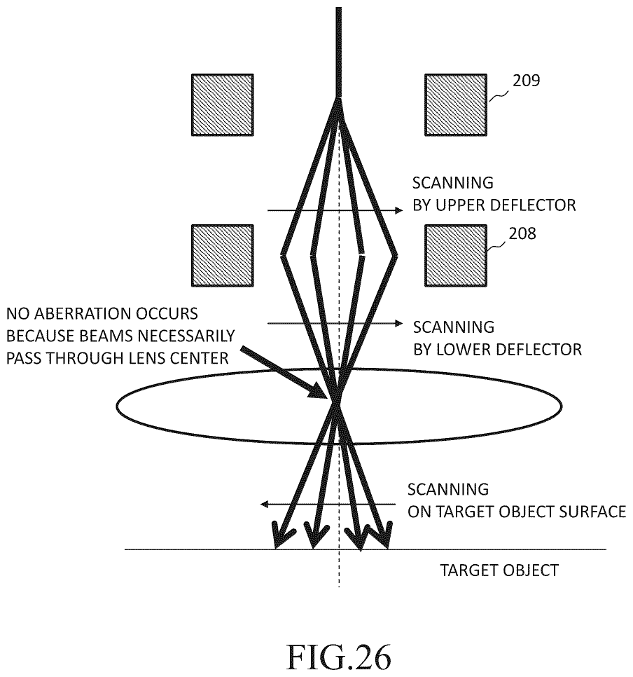

FIG. 26 is an illustration for explaining a scanning operation by a two-stage deflector in each Embodiment. FIG. 26 shows the case of performing the primary scanning by a two-stage deflector of a set of the upper and lower deflectors 209 and 208. For example, even when performing the primary scanning by the two-stage deflector (the upper and lower deflectors 209 and 208), it is possible to prevent an aberration from occurring because multiple primary electron beams pass through the center of the objective lens (electromagnetic lens 207).

In the above description, each “ . . . circuit” includes processing circuitry. The processing circuitry includes an electric circuit, a computer, a processor, a circuit board, a quantum circuit, a semiconductor device, or the like. Each “ . . . circuit” may use common processing circuitry (the same processing circuitry), or different processing circuitry (separate processing circuitry). Programs for causing a processor, etc. to execute processing may be stored in a recording medium, such as a magnetic disk drive, magnetic tape drive, FD, ROM (Read Only Memory) or the like. For example, the position circuit 107, the comparison circuit 108, the reference image generation circuit 112, the stage control circuit 114, the lens control circuit 124, the blanking control circuit 126, the deflection control circuit 128, the E×B control circuit 133, the deflection adjustment circuit 134, the multipole corrector control circuit 135, and the image combining circuit 138 may be formed by at least one processing circuit described above. For example, processing in these circuits may be carried out by the control computer 110.

Embodiments have been explained referring to specific examples described above. However, the present invention is not limited to these specific examples. Although FIG. 1 shows the case where the multiple primary electron beams 20 are formed by the shaping aperture array substrate 203 irradiated with one beam from the electron gun 201 serving as an irradiation source, it is not limited thereto. The multiple primary electron beams 20 may be formed by irradiation with a primary electron beam from each of a plurality of irradiation sources.

In the examples described above, the conversion table is generated in the inspection apparatus 100. However, it is not limited thereto. It is also preferable that a conversion table generated off-line outside the apparatus is input into the inspection apparatus 100 and stored in the storage device 66.

While the apparatus configuration, control method, and others not directly necessary for explaining the present invention are not described, some or all of them can be appropriately selected and used on a case-by-case basis when needed.

Further, any multiple charged particle beam alignment method and multiple charged particle beam inspection apparatus that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-electron beam image acquisition apparatus comprising:
a stage configured to mount thereon a target object;
a multiple primary electron beams forming device configured to form multiple primary electron beams;
a first deflector configured to scan the multiple primary electron beams over the target object by deflecting the multiple primary electron beams;
a corrector configured to correct a beam array distribution shape of multiple secondary electron beams emitted because the target object is irradiated with the multiple primary electron beams;
a second deflector configured to deflect the multiple secondary electron beams whose the beam array distribution shape has been corrected;
a detector configured to detect the multiple secondary electron beams having been deflected; and
a deflection control circuit configured to perform controlling to apply, to the second deflector, a superimposed potential obtained by superimposing a deflection potential which cancels out a position movement of the multiple secondary electron beams having moved along with scanning the multiple primary electron beams on a correction potential which corrects a distortion being generated due to correcting the beam array distribution shape of the multiple secondary electron beams and being dependent on a deflection amount for the scanning.

2. The apparatus according to claim 1, wherein
the distortion includes an error component of a trajectory of the multiple secondary electron beams generated due to the scanning with the multiple primary electron beams.

3. The apparatus according to claim 1, wherein
the second deflector dynamically corrects the distortion being generated due to correcting the beam array distribution shape of the multiple secondary electron beams and being dependent on a scanning position of the scanning the multiple primary electron beams.

4. The apparatus according to claim 1, further comprising:
a combined position distribution generation circuit configured to generate a combined position distribution by combining a detection position distribution of the multiple secondary electron beams which is generated due to the deflecting the multiple primary electron beams performed along with the scanning, and another detection position distribution of the multiple secondary electron beams which is generated due to deflection of the multiple secondary electron beams for cancelling out a position movement of the multiple secondary electron beams having moved along with the scanning the multiple primary electron beams, wherein
the deflection control circuit superimposes the correction potential which corrects an error between the combined position distribution and a design position distribution on the deflection potential.

5. The apparatus according to claim 1, wherein
the corrector is arranged on a trajectory of the multiple secondary electron beams between the first deflector and the second deflector.

6. A multi-electron beam image acquisition apparatus comprising:
a stage configured to mount thereon a target object;
a multiple primary electron beams forming device configured to form multiple primary electron beams;
a first deflector configured to scan the multiple primary electron beams over the target object by deflecting the multiple primary electron beams;
a second deflector configured to cancel out, by deflecting multiple secondary electron beams emitted because the target object is irradiated with the multiple primary electron beams, a position movement of the multiple secondary electron beams having moved along with scanning the multiple primary electron beams;
a corrector configured to correct a beam array distribution shape of the multiple secondary electron beams whose the position movement has been cancelled out by the deflecting the multiple secondary electron beams; and
a detector configured to detect the multiple secondary electron beams whose the beam array distribution shape has been corrected.

7. The apparatus according to claim 6, wherein
the corrector is arranged at a downstream side of the second deflector on a trajectory of the multiple secondary electron beams.

8. The apparatus according to claim 6, further comprising:
a combined position distribution generation circuit configured to generate a combined position distribution by combining a detection position distribution of the multiple secondary electron beams which is generated due to the deflecting the multiple primary electron beams performed along with the scanning, and another detection position distribution of the multiple secondary electron beams which is generated due to deflecting the multiple secondary electron beams for cancelling out a position movement of the multiple secondary electron beams having moved along with the scanning the multiple primary electron beams; and
a positional deviation amount calculation circuit configured to calculate an amount of positional deviation, generated in correcting the beam array distribution shape, between the combined position distribution and a design position distribution.

9. A multi-electron beam image acquisition method comprising:
forming multiple primary electron beams;
scanning, by a first deflector, the multiple primary electron beams over a target object mounted on a stage by deflecting the multiple primary electron beams;
correcting a beam array distribution shape of multiple secondary electron beams emitted because the target object is irradiated with the multiple primary electron beams;
deflecting the multiple secondary electron beams, whose the beam array distribution shape has been corrected, by a second deflector to which has been applied a superimposed potential obtained by superimposing a deflection potential for cancelling out a position movement of the multiple secondary electron beams having moved along with the scanning the multiple primary electron beams on a correction potential for correcting a distortion being generated due to the correcting the beam array distribution shape of the multiple secondary electron beams and being dependent on a deflection amount for the scanning; and
detecting the multiple secondary electron beams having been deflected, and outputting detection image data.

10. A multi-electron beam image acquisition method comprising:
forming multiple primary electron beams;
scanning, by a first deflector, the multiple primary electron beams over a target object mounted on a stage by deflecting the multiple primary electron beams;
cancelling out a position movement of multiple secondary electron beams, which are emitted because the target object is irradiated with the multiple primary electron beams, having moved along with the scanning the multiple primary electron beams by deflecting the multiple secondary electron beams by a second deflector;
correcting a beam array distribution shape of the multiple secondary electron beams whose the position movement has been cancelled out by the deflecting the multiple secondary electron beams; and
detecting the multiple secondary electron beams whose the beam array distribution shape has been corrected, and outputting detection image data.
